(19) United States
(12) Patent Application Publication
(10) Pub. No.: US 2025/0250125 A1
(43) Pub. Date: Aug. 7, 2025

(54) SHALLOW-DEPTH EQUIPMENT FRONT END MODULE WITH ROBOT

(71) Applicant: Lam Research Corporation, Fremont, CA (US)

(72) Inventor: Richard M. Blank, San Jose, CA (US)

(21) Appl. No.: 18/857,441

(22) PCT Filed: Apr. 20, 2023
(86) PCT No.: PCT/US2023/019308

§ 371 Date: Oct. 16, 2024

Related U.S. Application Data
(60) Provisional application No. 63/363,470, filed on Apr. 22, 2022.

(51) Int. Cl. B65G 47/90; H01L 21/687

(52) U.S. Cl. CPC B65G 47/90; H01L 21/68707

(57) ABSTRACT

Shallow-depth equipment front end modules are provided that use one or more robot arms that have no rotational joints, other than at the robot arm shoulder. In some such implementations, robot arms may pick and place wafers from or into FOUPs or load locks by coordinating translational movement of the robot arm base with rotation of the robot arm relative to the robot arm base. In some other such implementations, the robot arm(s) used may be telescoping arms and the translational movement of the robot arm base and the rotation of the robot arm relative to the robot arm base may be decoupled.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Semiconductor processing tools typically feature a plurality of semiconductor processing chambers arranged about a vacuum transfer module. Wafers may be provided to a semiconductor processing tool via a front-opening unified pod (FOUP). A FOUP is a container that is configured to store a plurality of semiconductor wafers, e.g., 25, in a stacked arrangement, thereby allowing the plurality of semiconductor wafers to be transported between semiconductor processing tools as a group.

The FOUPs may typically be delivered to load ports that are arranged along one or more walls of what is referred to as an equipment front end module (EFEM). Each load port may include a platform that is configured to locate and receive a FOUP, and may also include a FOUP door-opening mechanism that is configured to engage with, and remove, a removable FOUP door from the FOUP, thereby allowing access to the wafers that are inside the FOUP by one or more wafer handling robots that are located within the EFEM.

The EFEM may generally serve as a semi-controlled environment through which wafers may be passed from the FOUPs to load locks leading to a vacuum transfer module (VTM) that is connected with one or more semiconductor processing chambers. The load lock or load locks may each act as an airlock that can accommodate one or more of the wafers while the atmosphere within the load lock, and surrounding the wafer(s), is pumped down to a pressure that is in equilibrium with, or near equilibrium with, the sub-atmospheric pressure within the VTM or pumped up from the sub-atmospheric VTM pressure to the pressure within the EFEM.

As noted above, an EFEM may include one or more robots that may be used to transfer wafers between the FOUPs and the load lock(s). The robot(s) may reside within the interior of the EFEM, which may be a relatively open space through which forced air may be flowed, e.g., from the top to the bottom, in order to reduce the chances of particulates being transported from the FOUPs to the load locks as the wafers transit therethrough.

Discussed herein are new EFEM concepts that improve on existing EFEM designs.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes an equipment front-end module (EFEM) enclosure for handling semiconductor wafers having a nominal diameter of D. The EFEM enclosure may have a first wall defining a bolt plane for load ports and a second wall opposite the first wall and defining a load lock plane. The bolt plane and the load lock plane may be spaced apart from one another by a first distance greater than D and less than 1.75 D. The apparatus may further include a first robot arm base located within the EFEM enclosure and a first robot arm supported by, and coupled with, the first robot arm base such that the first robot arm is rotatable relative to the first robot arm base about a first axis. The first axis may be located within 40% to 60% of the first distance from the bolt plane and within 40% to 60% of the first distance from the load lock plane. The apparatus may further include a first linear translation system configured to move the first robot arm base along a second axis parallel to the bolt plane.

In some implementations, the first distance may be greater than D and less than 1.65 D. IN some further such implementations, the first distance may be greater than D and less than 1.6 D.

In some implementations, the apparatus may further include a plurality of load ports arranged in a linear array along an exterior of the first wall, each load port having a corresponding interface configured to receive and locate a corresponding FOUP on that load port such that wafers in that FOUP are nominally centered above a corresponding target location on that load port. The two load ports of the plurality of load ports that are furthest from each other may have corresponding target locations that are spaced apart from one another by a distance X, and the first linear translation system may be configured to translate the first robot arm base along the second axis by a second distance of at least X.

In some implementations, the first robot arm may include a first robot arm link that ends in a first end effector configured to support a wafer, and the first robot arm link and the first end effector may be rotationally fixed relative to each other and rotate as a single structure when the first robot arm link is caused to rotate relative to the first robot arm base.

In some such implementations, a tip of the first end effector furthest from the first axis may be a third distance from the first axis and the third distance is greater than 1.3 D. In some such implementations, the third distance may be greater than 1.4 D. In some further such implementations, the third distance may be greater than 1.6 D.

In some implementations, the first robot arm link and the first end effector may be fixed, both rotationally and translationally, relative to each other.

In some implementations, the first linear translation system may be configured to translate the first robot arm base along the second axis by a distance of at least X+D. In some such implementations, the EFEM enclosure may have opposing end walls spanning between the first wall and the second wall, a first extension region of the EFEM enclosure may be bracketed between one of the end walls and the load port closest thereto, and the first extension region may have a length along the second axis of at least D.

In some implementations, the apparatus may further include a second robot arm base located within the EFEM enclosure and a second robot arm supported by, and coupled with, the second robot arm base such that the second robot arm is rotatable relative to the second robot arm base about a rotational axis. The rotational axis may be located within 40% to 60% of the first distance from the bolt plane and within 40% to 60% of the first distance from the load lock plane. The first linear translation system may be further configured to move the second robot arm base along the second axis.

In some such implementations, the EFEM enclosure may have opposing end walls spanning between the first wall and the second wall, a first extension region of the EFEM enclosure may be bracketed between one of the end walls and the load port closest thereto, a second extension region of the EFEM enclosure may be bracketed between the other of the end walls and the load port closest thereto, and the first extension region and the second extension region may each have a length along the second axis of at least D.

In some implementations, the apparatus may further include one or more alcoves located in the first wall or the second wall. Each alcove may have an interior surface facing towards an interior of the EFEM enclosure that is at least as far from a reference plane coincident with the first axis and parallel to the load lock plane as an end of the first robot arm furthest from the first axis is from the first axis. Each alcove may be sized large enough that the end of the first robot arm furthest from the first axis is insertable into that alcove without coming into contact with walls defining that alcove when the first robot arm is extended such that the end of the first robot arm furthest from the first axis is also furthest from the first wall.

In some such implementations, the second wall may include one or more load lock openings, at least one of the one or more alcoves may be located in the second wall and may be positioned above or below the load lock openings, the first robot arm base may include a vertical lift mechanism that is configured to translate the first robot arm between at least a first vertical position and a second vertical position along a vertical axis, the first robot arm, in the first vertical position, may be positioned such that the end of the first robot arm furthest from the first axis is at an elevation that is within a first elevation range spanned by at least one of the one or more load lock openings, and the first robot arm, in the second vertical position, may be positioned such that the end of the first robot arm furthest from the first axis is at an elevation that is within a second elevation range occupied by at least one of the one or more alcoves.

In some implementations, the second wall may include one or more load lock openings, and at least one of the one or more alcoves may be located in the second wall and may be positioned to the side of at least one of the load lock openings.

In some implementations, the apparatus may include a controller having one or more processors and one or more memory devices, the one or more memory devices storing computer-executable instructions for causing the one or more processors to a) cause the first linear translation system to move the first robot arm base along the second axis during a first time interval and by a first amount while the first robot arm is in a first rotational position relative to the first robot arm base and b) cause the first linear translation system to move the first robot arm base along the second axis during a second time interval and by a second amount while simultaneously causing the first robot arm to rotate relative from the first rotational position relative to the first robot arm base to a second rotational position relative to the first robot arm base. The first robot arm, in the first rotational position relative to the first robot arm base, may be entirely between the load lock plane and the bolt plane, and the first robot arm, in the second rotational position relative to the first robot arm base, may extend through the bolt plane.

In some such implementations, the first robot arm may be configured to support a wafer during wafer transfer operations within the EFEM enclosure such that a center point of the wafer is positioned above and centered over a wafer target location defined for the first robot arm, and the one or more memory devices may store further computer-executable instructions for causing the one or more processors to cause the first robot arm base to be in a first horizontal position at the start of the second time interval, and cause, during most or all of the second time interval, the first robot arm to rotate to angular displacements from the first rotational position relative to the first robot arm base determined according to the function

$$a cos ( \frac{\partial }{α} ) \cdot \frac{180 °}{π} ,$$

where δ=a distance from the first axis to the wafer target location, α=the displacement of the first robot arm base from the first horizontal position, and π=the numeric constant pi.

In some implementations, the first robot arm may include a first portion, a second portion, and a third portion. The third portion may be rotatably connected with the first robot arm base, the first portion may include an end effector, and the first portion may be configured to translate relative to the second portion, and the second portion relative to the third portion, such that the first robot arm is able to be transitioned between an extended state and a retracted state responsive to receipt of one or more control signals.

In some such implementations, the first portion, the second portion, and the third portion may each have a length that is equal to or less than D. In some additional or alternative such implementations, the first robot arm may be configured such that the first portion moves relative to the second portion simultaneously with movement of the second portion relative to the third portion.

In some such implementations, the first portion may be connected with the third portion by one or more pairs of belt portions, and each belt portion may pass over a corresponding pulley that is rotatably mounted to the second portion.

In some implementations, the apparatus may further include a second linear translation system configured to cause the second portion to translate relative to the first portion.

In some implementations, the first robot arm may include a first robot arm link that is configured to be rotatable relative to the first robot arm base about the first axis, the first robot arm may further include a second robot arm link that is rotatably connected with the first robot arm link so as to be rotatable relative to the first robot arm link, and the first robot arm may be configured such that the second robot arm link is configured to be rotatable relative first robot arm link independent of rotation of the first robot arm link relative to the first robot arm base.

In some implementations, the second robot arm link may be configured to rotate about an elbow axis relative to the first robot arm link, the second robot arm link may include a first end effector configured to support a wafer such that the wafer is centered on a target location that is fixed with respect to the first end effector, and a first distance between the target location and the elbow axis may be greater than a second distance between the elbow axis and the first axis. In some such implementations, the second distance may be less than D.

In some implementations, a distance between the first axis and the portion or portions of the first robot arm link that are furthest from the first axis may be less than or equal to D.

### BRIEF DESCRIPTION OF THE DRAWINGS

Reference to the following Figures is made in the discussion below; the Figures are not intended to be limiting in scope and are simply provided to facilitate the discussion below.

FIGS. 1A through 1K depict an example implementation of a shallow-depth EFEM during various stages of operation.

FIGS. 2 and 3 depict an example implementation of a shallow-depth EFEM having an alcove for temporarily parking a wafer during a Y-turn operation during different stages of operation.

FIG. 4 depicts another example implementation of a shallow-depth EFEM having an alcove for temporarily parking a wafer during a Y-turn operation.

FIGS. 5A through 5F depict an example implementation of a shallow-depth EFEM having an extension region to accommodate a greater range of movement of a robot arm base during various stages of operation.

FIG. 6 is a diagram of an example implementation of a shallow-depth EFEM with two separately controllable robot arms.

FIGS. 7A through 7H depict another example implementation of a shallow-depth EFEM during various stages of operation.

FIG. 8 depicts a side section view of an example multiple-link robot arm.

FIG. 9 shows an example telescoping robot arm in a retracted state.

FIG. 10 shows the example telescoping robot arm of FIG. 9 in the extended state.

FIG. 11 shows the example telescoping robot arm of FIG. 9 in an exploded state.

FIGS. 12A through 12H depict an example implementation of a shallow-depth EFEM having a telescoping robot arm during various stages of operation.

FIG. 13 depicts various perspective views of an example implementation of a robot arm base and a telescoping robot arm.

FIG. 14 depicts a side view diagram of an example implementation of a shallow-depth EFEM.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

Semiconductor processing tools are typically very large tools. Each such semiconductor processing tool has an associated footprint that determines how much floor space (both in total area and in shape) the semiconductor processing tool will require in order to be installed in a semiconductor processing fabrication plant, or fab. As fabs are extremely expensive, companies that operate fabs have an interest in maximizing the number of semiconductor processor tools that may be housed within them, as such maximization will increase the efficiency of the fab and result in a larger return on investment for the fab operator. Reduction of the footprint of a given semiconductor processing tool will, for a certain number of such semiconductor processing tools, result in more such semiconductor processing tools being able to fit within a given area than would be possible with a larger-sized footprint.

Discussed herein are EFEMs that may have a shallower depth than existing EFEMs and/or have a less complicated robot mechanism, thereby reducing the footprint of the semiconductor processing tool with of which they are a part and/or reducing the cost and complexity of the EFEM.

The EFEMs discussed herein feature a generally elongate, rectangular EFEM enclosure that may have two opposing long walls. A series of load port openings may be located along one of the two opposing long walls, while one or more load lock openings may be located along the other opposing long wall. It will be immediately apparent that the opposing long walls must, at a minimum, be spaced apart by the diameters of the wafers that the EFEM is designed to handle, e.g., 300 mm, in order to allow the wafer to be transported horizontally within the EFEM.

However, additional spacing is also required, e.g., by Semiconductors Equipment and Material International (SEMI) standards. For example, SEMI standards define what is referred to as a “BOLTS interface” (also referred to in the industry as a “bolt plane”) that is a surface of the EFEM enclosure to which load ports are to be attached. Load ports are designed to have a common interface with EFEMs to allow different load ports to be interchangeably mounted to a given EFEM. This common interface is generally a flat surface on the exterior of the EFEM with a particular pattern of threaded holes that are positioned around a large rectangular opening so as to interface with bolts that may be passed through similarly positioned holes on a load port. The rectangular opening is sized to provide enough clearance to allow a FOUP door to be removed from the FOUP and slid downward so as to no longer block any part of the FOUP, thereby allowing wafers to be removed from, or placed into, the FOUP. The SEMI standards specify that load ports may utilize the space inboard of the bolt plane up to a depth of 4 inches to accommodate the hardware and mechanism movement needed for the FOUP door opening mechanism. Thus, an additional 4 inches of depth (a clearance zone), at a minimum, must be added to the wafer diameter in determining the minimum spacing between the opposing long walls of an EFEM.

The long wall in which the load lock or load locks are located may also have a region in which a clearance zone for load lock hardware, e.g., load lock door opening mechanisms, active wafer centering (AWC) sensors, or other equipment, may be provided. For example, load locks may have narrow, horizontal slot openings through which wafers may be passed. Such an opening may be sealed by an external door that may press against a surface of the load lock that is flush with the interior surface of the long wall in which the load lock is located (or otherwise generally closest to the interior of the EFEM enclosure). The door may be supported by a rocker/translation system that allows the door to pivot or translate horizontally inward (towards the interior of the EFEM enclosure) by a small amount, e.g., sufficient to ensure there is no contact between the door and the load lock, and to then translate downward, thereby allowing unobstructed access through the slot/opening to the load lock. Such door mechanisms, if used, may also require additional clearance space. For example, a further 2 inches of depth may be required in the EFEM enclosure, in some cases, to accommodate such hardware.

There must also be sufficient clearance for the robot arm or arms that are provided within the EFEM to typically be able to rotate through at least 180° without having any part of the robot arm(s) or the wafer supported thereby enter the clearance zones that may be present adjacent to each long wall. In some multi-joint robot arms, this may be particularly problematic, as such robot arms may have arm links and joints that protrude out beyond the edge of the wafer, thereby expanding the depth of the zone within which the robot arm and wafer may move during wafer transit operations along the length of the EFEM. Of course, the robot arm and wafer may cross out of that zone and into the clearance zones when a wafer is actually being placed into or removed from a FOUP or a load lock.

The present inventor realized that an EFEM could be produced that had a minimum or near-minimum depth (with depth referring to the distance between the bolts plane and the load lock plane, i.e., the plane that is defined by the major surface of the load lock that is generally closest to the interior of the EFEM—such a surface is typically flush, or nearly flush, with the inward-facing surface of the EFEM enclosure for the wall in which the load lock is mounted). Such an EFEM could, for example, have a depth that was equal to the wafer diameter plus the mandated SEMI clearance zone of 4 inches, plus, if necessary, any clearance zone needed to accommodate load lock door hardware, and any desired tolerance gaps. For a 300 mm wafer, for example, such an EFEM might have such a depth in the range of 18.5 inches or lower, which may be on the order of 25% shallower than EFEMs that do not utilize such an arrangement. This, in turn, may act to decrease the overall footprint of the semiconductor processing tools that utilize such EFEMs as compared with equivalent semiconductor processing tools that do not. This allows for an increased number of such semiconductor processing tools to be housed within a given area, thereby potentially increasing fab throughput and allowing the floor space of the fab to be put to more efficient use.

Example shallow-depth EFEMs with a variety of different types of robot arms are discussed herein; it will be understood that, generally speaking, each type of robot arm may be substituted for the other in the various examples discussed herein, unless such substitution would, for evident reasons, prove unworkable.

In one robot arm type discussed herein, the robot arm is a single-link robot arm, e.g., having a rigid arm that terminates in an end effector that is configured to support a wafer. Such a robot arm may have no rotational joints other than a single rotational joint at the end of the robot arm that allows it to be rotated relative to the base that supports it (thereby allowing the robot arm to rotate about a single rotational axis). It will be understood that such a single-link robot arm may have adjustment mechanisms that allow for some small amount of rotation between portions of the robot arm to occur, e.g., to fine-tune the position of the end effector relative to the remainder of the robot arm, but that such adjustment mechanisms do not constitute a “rotational joint” for the purposes of this disclosure. In other words, a rotational joint is to be understood to refer to a rotational interface between two components that allows for gross relative angular movement between those two components, e.g., on the order of tens or hundreds of degrees of relative rotation, while the robot arm is in use, e.g., being used to move a wafer. Components of a single-link robot arm, for example, would be configured to be immovable relative to one another during normal operational use of such a robot arm. It will be understood, however, that such components may still move a small amount relative to one another due, for example, to gravitational effects and flexure within the arm itself. Such movement, however, is minor and will be understood not to negate the otherwise immovable nature of the arm.

Another type of robot arm discussed herein is a multi-link robot arm, e.g., one with two or more links that are connected with one another via intervening rotational joints.

A third type of robot arm type discussed herein is a telescoping robot arm. Unlike a single-link robot arm in which the end effector is maintained at a fixed distance from the center of rotation of the arm, a telescoping robot arm may have two or more portions that are configured to translate relative to one another, thereby allowing a portion of the robot arm having the end effector to move radially inward or outward relative to the rotational center of the robot arm.

Other types of robot arms may be used in the shallow-depth EFEMs discussed herein; it will be appreciated that the present disclosure extends to the use of such robot arms in shallow-depth EFEMs as well. The three robot arm types discussed above, however, may provide for varying levels of wafer placement accuracy and/or less expensive robot mechanisms due to the lack, or low number, of rotational joints along the length of the robot arms. The single-link robot arm, in some implementations, may offer the least expensive robot arm solution and provide the highest wafer placement accuracy due to the fact that it only has two kinematic interfaces that support movement (and that are therefore potential sources of positioning variance)—the rotatable shoulder joint and the translatable robot arm base. By eliminating all other kinematic interfaces in such a robot arm, the potential sources of misalignment in the robot arm are minimized, thereby reducing the potential misalignment that may occur. A multi-link robot arm having two links and an elbow joint would, of course, have an additional degree of freedom, but may also be somewhat more flexible in its movement range, thereby allowing such an arm to be able to navigate around obstacles more readily.

Several examples of shallow-depth EFEM systems are discussed below, most featuring a single-link robot arm. However, it will be understood that each of the implementations discussed below may, if desired, be implemented using a different type of robot arm from what is used in the particular example discussed. For example, a single-link robot arm may be used in place of a telescoping robot arm and/or a multi-link robot arm, and vice versa. It will also be understood that various dimensional relationships that are discussed with respect to one implementation below are also equally applicable to the other implementations below unless clearly incompatible therewith (for example, a relationship between wafer diameter and single-link robot arm length would not necessarily be applicable to a telescoping robot arm since the two robot arms operate in a completely different manner, and the single-link robot arm structure is not present in the telescoping robot arm scenario).

Various example implementations of shallow-depth EFEMs are discussed below with reference to the Figures.

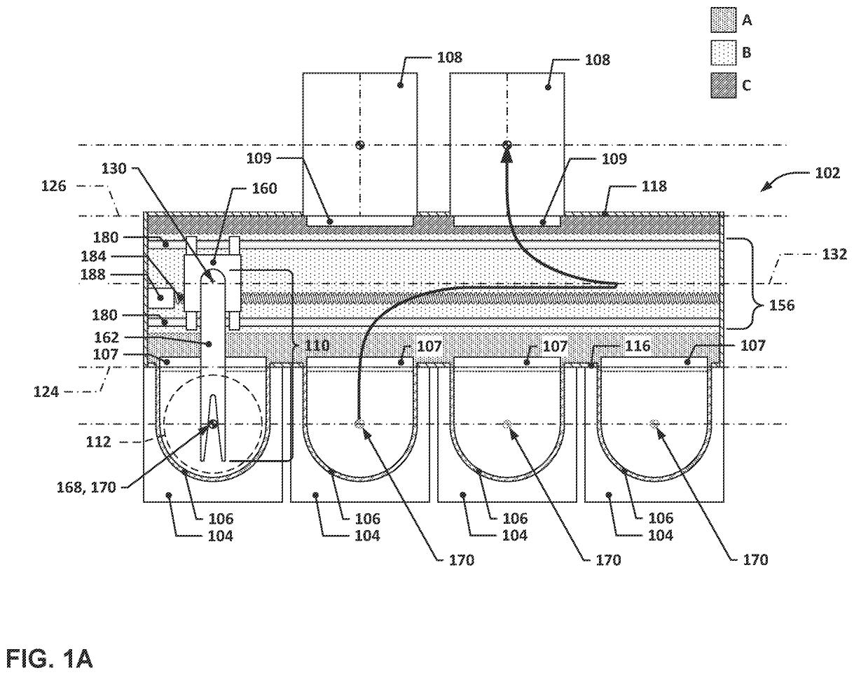

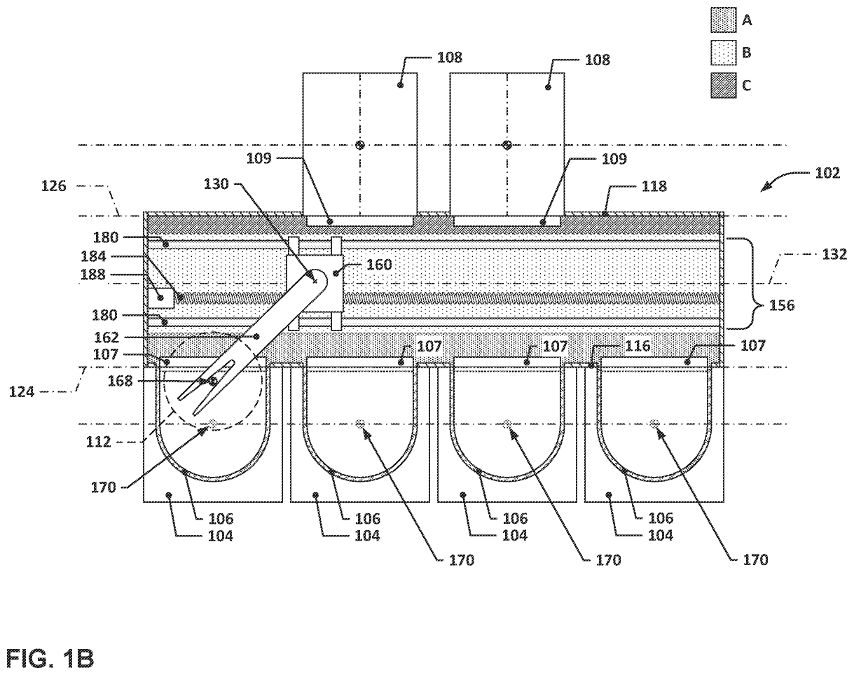

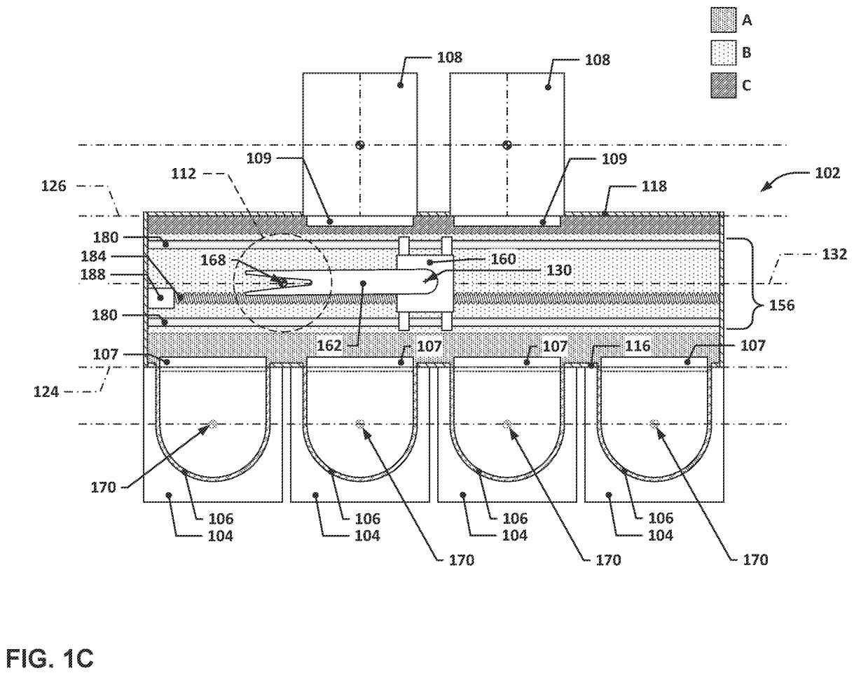

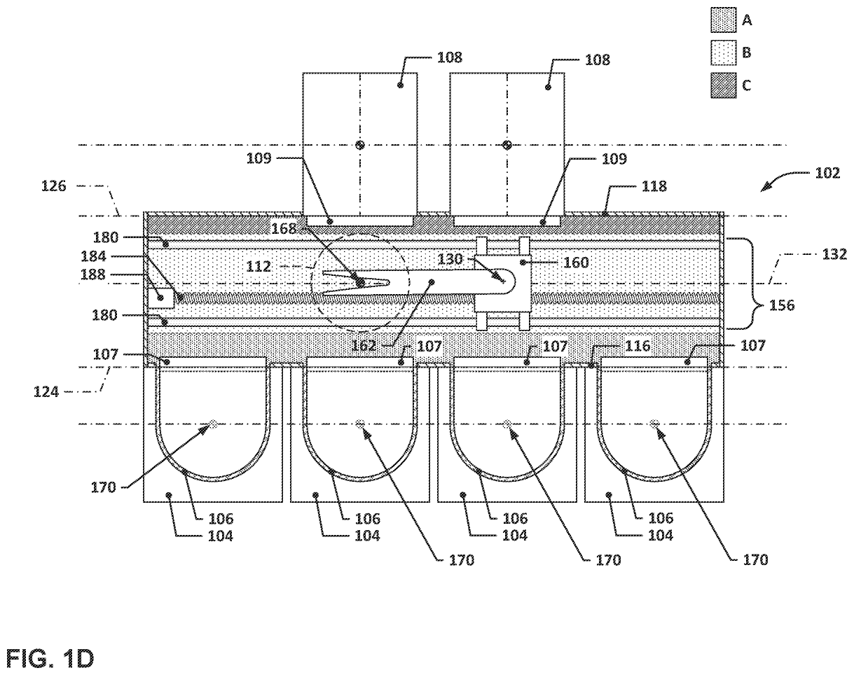

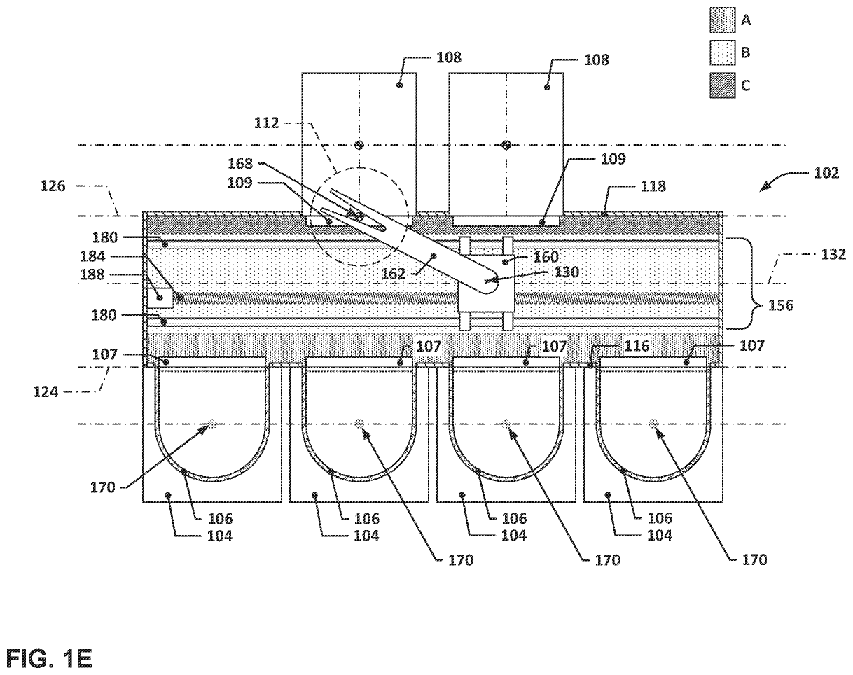

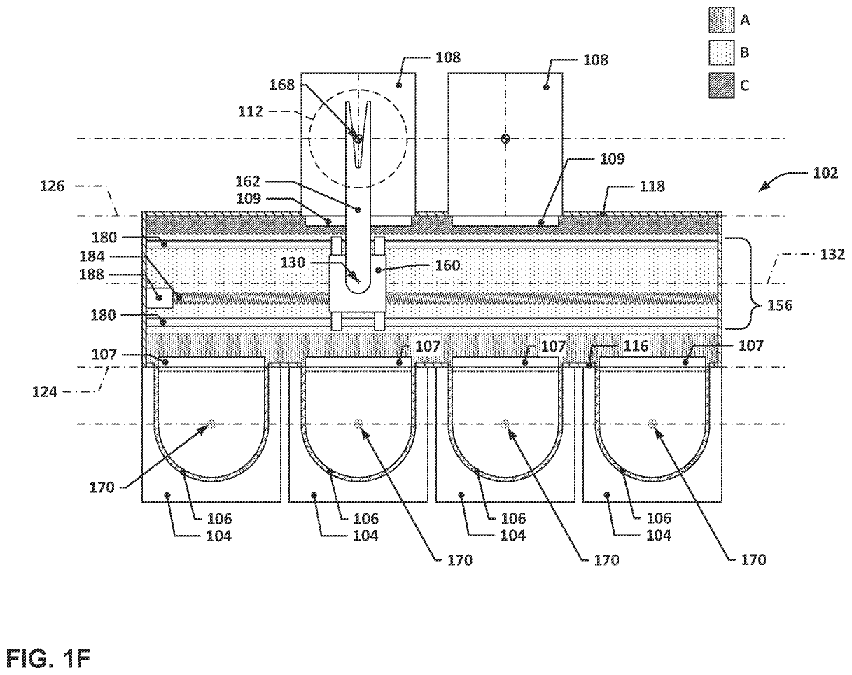

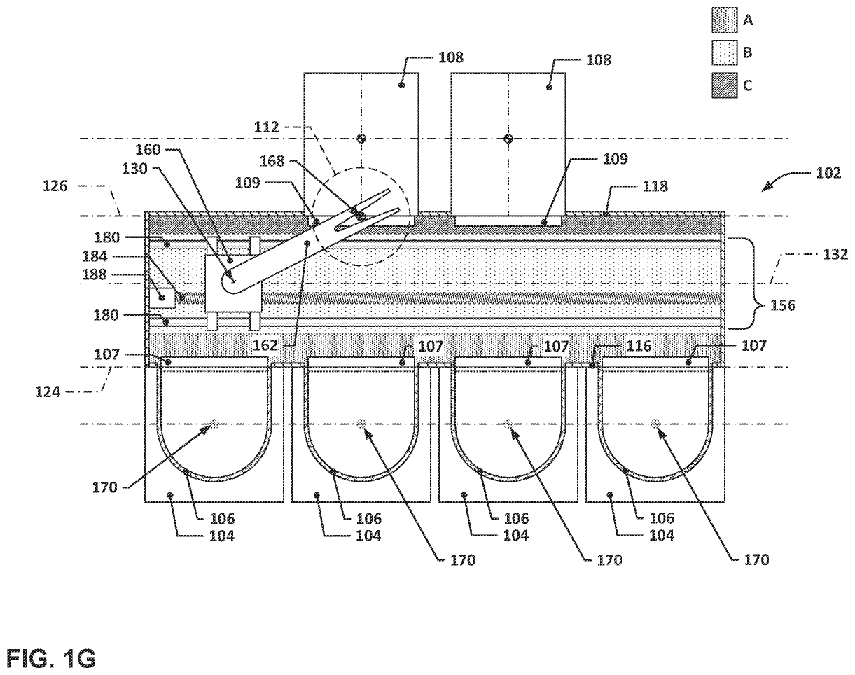

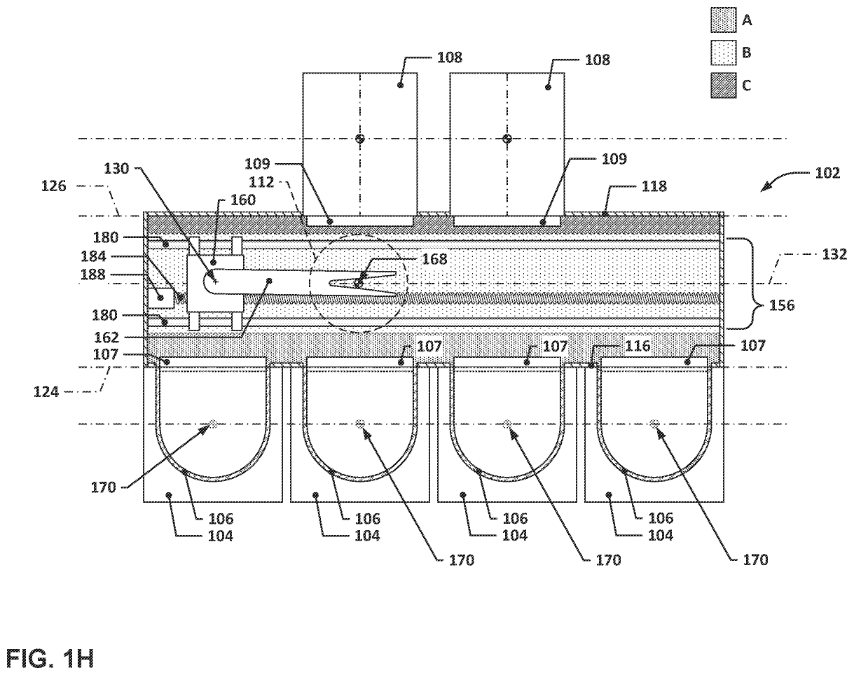

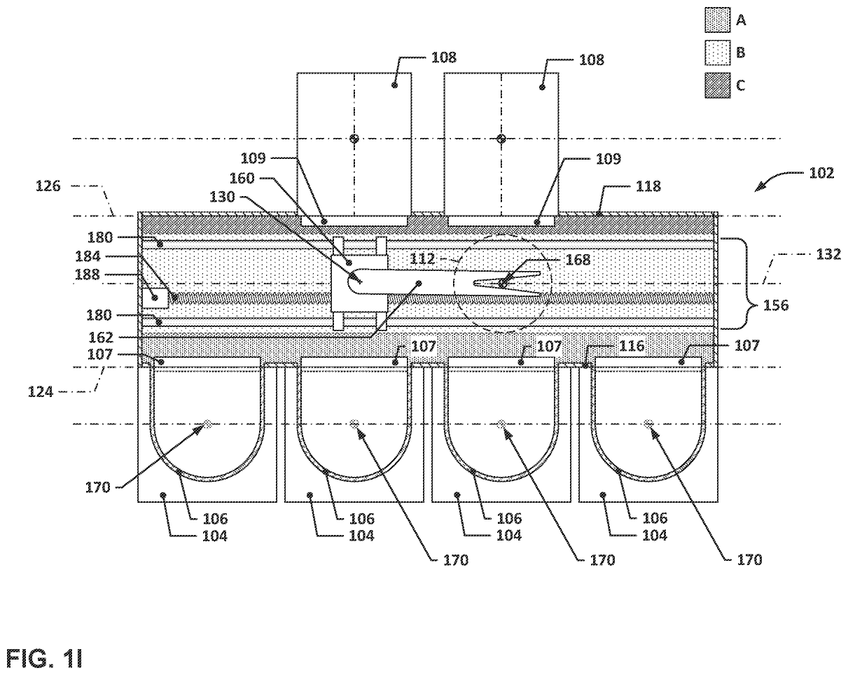

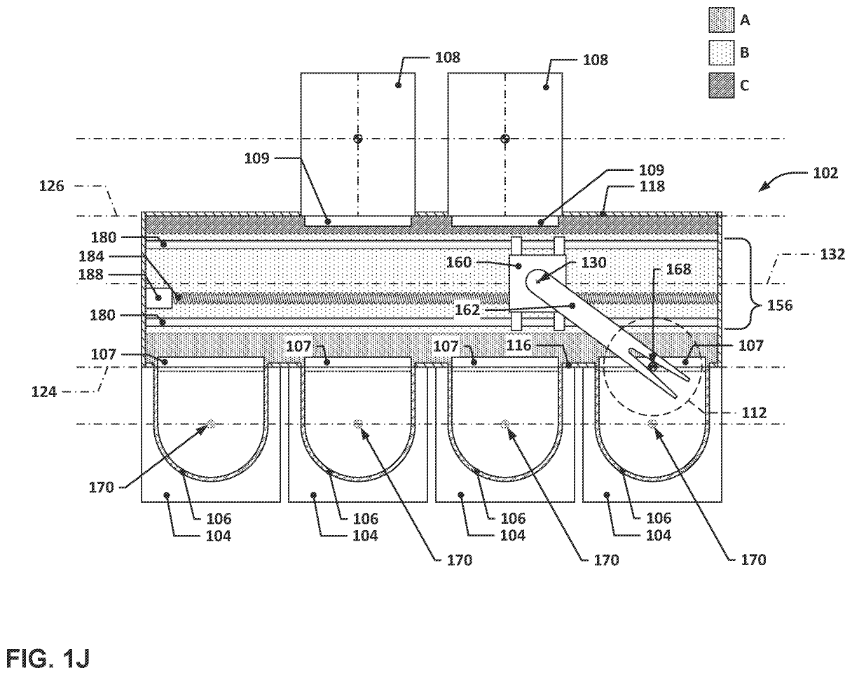

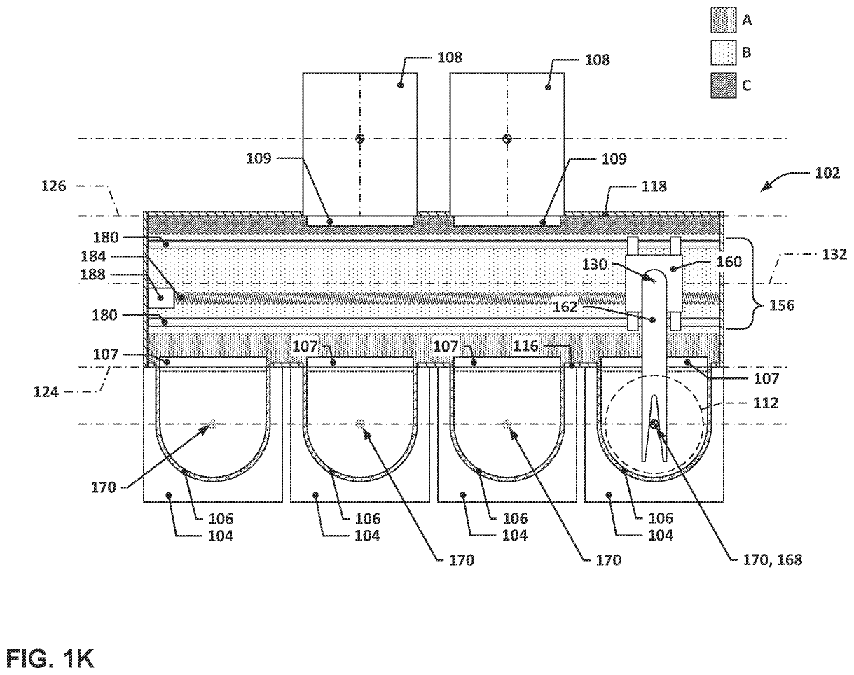

FIGS. 1A through 1K depict schematics of a shallow-depth EFEM according to the present disclosure. The elements in each of FIGS. 1A through 1K are the same but shown during various stages of operation. As can be seen, the EFEM has an EFEM enclosure 102 that generally includes four walls, including a first wall 116 and a second wall 118 that define a long horizontal axis of the EFEM. Two end walls (not called out but spanning between the first wall 116 and the second wall 118) may also be included in the four walls. The EFEM enclosure 102 may also include a ceiling, which is typically provided by a fan filter unit that is configured to force air down into the EFEM enclosure 102 and through vents in a floor of the EFEM enclosure 102.

The EFEM enclosure 102 shown in FIGS. 1A through 1K features four load ports 104 that are arranged in a linear array and spaced apart along an exterior of the first wall 116. The load ports 104 are each interfaced to the EFEM enclosure 102 at a bolt plane 124, as discussed earlier herein. Each load port 104 may have a corresponding interface that is configured to receive and locate a FOUP on that load port. FOUPs are typically conveyed throughout a FAB using an automated material handling system (AMHS), which includes a network of elevated tracks and automated conveyors that are suspended from the tracks. The automated conveyors are equipped with hoist systems that allow them to lower FOUPs 106 onto, or lift FOUPs 106 off of, load ports 104, thereby allowing FOUPs 106 to be moved between load ports and semiconductor processing tools. The interfaces on the load ports for receiving the FOUPs 106 have features that cause the FOUPs 106, as they are lowered onto the load ports, to be guided into a particular position relative to the load ports, e.g., such that the wafers that are housed within that FOUP 106 (or that are to be placed into that FOUP) are nominally centered above a corresponding target location 170 on that load port. The target locations 170 of the two endmost load ports may be separated from one another by a distance X. It will be understood that the EFEM enclosure 102 may also be interfaced with fewer or greater numbers of load ports 104, e.g., two load ports 104, three load ports 104, five load ports 104, or six load ports 104.

The grey shaded zone “A” indicates a region within the EFEM enclosure 102 that is designated as a clearance zone to accommodate the presence and operation of FOUP door 107 opening mechanisms.

The depicted EFEM enclosure 102 is also connected with two load locks 108 that are interfaced with the second wall 118 of the EFEM enclosure 102. As can be seen, the load locks 108 each have a major surface that faces towards the interior of the EFEM enclosure 102; this surface may generally be flush with, or nearly flush with, the inner surface of the second wall 118 and may define a load lock plane 126. The dark grey shaded zone “C” indicates a region within the EFEM enclosure 102 that is designated as a clearance zone to accommodate the presence and operation of load lock doors 109. It will be understood that fewer or greater numbers of load locks 108 may be used, e.g., one load lock, three load locks, four load locks, etc. In some cases, a single housing load lock housing may contain multiple load locks 108.

Also located in between the first wall 116 and the second wall 118 is a robot transit corridor “B,” which is a region of the EFEM enclosure 102 that is reserved for use by a first robot arm 110. The first robot arm 110, as shown in this example, is a single-link robot arm having a first robot arm link 162 that is rotationally coupled to a first robot arm base 160 so as to be rotatable about a first axis 130 relative to the first robot arm base 160. The first robot arm link 162 may terminate in an end effector 164 which may be, for example, a blade-type end effector and which may be used to support a semiconductor wafer 112 during wafer transfer operations within the EFEM enclosure 102. The end effector 164 may be rotationally and translationally fixed with respect to the first robot arm link 162, e.g., such that the end effector 164 and the first robot arm link 162 rotate together as a unit or single structure when the first robot arm 110 is caused to rotate about the first axis 130 and such that the length of the first robot arm 110 cannot be actively changed during operation. It will be understood that “fixed,” as the term is used herein to refer to the relationship between two parts, components, or structures, may include structures that are immovably positioned relative to one another, but may also include structures that are adjustable relative to one another but which are not moved relative to each other during normal operation. E.g., an end effector may have alignment features that allow for the positioning of the end effector relative to the arm to which it is attached to be adjusted/tuned-once adjusted or tuned, the end effector would be immobilized relative to the arm and considered to be “fixed” with respect to the arm. “Fixed” may also be used to refer to structures that are immobilized relative to each other but which may still move small amounts relative to each other due to elastic deflection.

The end effector may be configured to support the wafer 112 such that the wafer 112 is nominally centered on a wafer target location 168 that is fixed with respect to the end effector 164. The wafer target location 168, in this view, is actually directly over the target location 170 of the left-most load port 104 due to the fact that the first robot arm 110 is in a position that it would be in when transferring the wafer 112 to, or retrieving the wafer 112 from, the left-most FOUP 106.

The first robot arm base 160 may, as shown in FIGS. 1A through 1K, be supported by a first linear translation system 156, which, in this example, may include a pair of first linear guides 180, e.g., rails, that may engage with bearings or rollers on the first robot arm base 160 and allow the first robot arm base 160 to translate along a second axis 132, e.g., in a direction parallel to the bolts plane 124 and/or the load lock plane 126. A first drive screw 184 coupled to a first drive motor 188 may be rotated in order to cause the first robot arm base 160, which may have a nut (not shown) that is fixed with respect to the first robot arm base 160 and through which the first drive screw 184 may be threaded, to translate along the first linear guides 180. This allows the first robot arm base 160 to be repositioned within the EFEM enclosure 102. Generally speaking, the first linear translation system 156 may be configured to translate the first robot arm base 160 along the second axis 132 by a second distance equal to or greater than the distance X. In some implementations, the first linear translation system 156 may be configured to translate the first robot arm base 160 along the second axis 132 by a second distance equal to or greater than the distance X minus the distance between the target location 170 of one of the two end-most load ports and the target location 170 of the load port 104 closest to it. In such an implementation, the first robot arm base 160 may, in order to access FOUPs 106 located at the endmost load ports 104, be moved to locations where the first axis 130 is equidistant from the target locations 170 of either the two left-most load ports 104 or the two right-most load ports 104. In such an arrangement, the first robot arm 110 may, for example, be positioned so as to extend along oblique angles with respect to the second axis 132 in order to reach into the FOUPs 106 located at the endmost load ports 104.

The bolt plane 124 and the load lock plane 126 may be spaced apart from one another by a first distance that is greater than a nominal diameter D of the wafer 112 but less than 1.75 D. In some implementations, the first distance may also be less than 1.65 D or also less than 1.6 D. The lower the first distance is, the shallower the depth of the EFEM enclosure 102 may be.

The first axis 130 of the first robot arm 110 may be positioned within 40% to 60% of the first distance from the load lock plane 126 and within 40% to 60% of the first distance from the bolts plane 124, e.g., generally centered between the bolts plane 124 and the load lock plane 126. In some implementations, the more centered the first axis 130 is between the bolts plane 124 and the load lock plane 126, the shallower the depth of the EFEM enclosure 102 may be. In some implementations, the first axis 130 of the first robot arm 110 may be positioned within 45% to 55% of the first distance from the load lock plane 126 and within 45% to 55% of the first distance from the bolts plane 124, and in some further implementations, the first axis 130 of the first robot arm 110 may be positioned within 48% to 52% of the first distance from the load lock plane 126 and within 48% to 52% of the first distance from the bolts plane 124. In some implementations, the first axis 130 of the first robot arm 110 may be positioned halfway between the load lock plane 126 and the bolts plane 124.

The first robot arm 110 may have a length (measured with respect to the first axis 130) that is selected so as to be sufficiently long enough that the tip or tips of the end effector 164 that are farthest from the first axis 130 are at least able to reach beyond the target location 170 of each FOUP 106 when the first linear translation system 156 is caused to position the first axis 130 in front of that FOUP 106 and the first robot arm 110 caused to extend into that FOUP 106. For example, the tip or tips of the end effector 164 furthest from the first axis 130 may be a third distance from the first axis 130. The third distance may, for example, be greater than 1.3 D, greater than 1.4 D, greater than 1.5 D, greater than 1.6 D, greater than 1.7 D, or greater than 1.8 D.

The system of FIGS. 1A through 1K may also include a controller that includes one or more processors and one or more memory devices. The one or more memory devices may store computer-executable instructions for controlling the one or more processors to cause, for example, the first linear translation system 156 and/or a motor in the first robot arm base 160 that controls rotation of the first robot arm 110 about the first axis 130 to actuate.

Due to the compactness of the EFEM enclosure 102, the controller may be configured to coordinate translational movement of the first robot arm base 160 by the first linear translation system 156 and rotational movement of the first robot arm 110 about the first axis 130. For example, with respect to the implementation of FIGS. 1A through 1K, the first robot arm base 160 may be caused to translate to the right from the indicated position while the first robot arm 110 may simultaneously be caused to rotate in a clockwise manner. Such rotational movement may generally be according to the function:

$$a cos ( \frac{\partial }{α} ) \cdot \frac{180 °}{π}$$

where the function indicates rotational movement from the position shown in FIG. 1C, δ=a distance from a reference plane that is coincident with the second axis 132 and parallel to the bolts plane 124 to the wafer target location, α=the displacement of the first robot arm base from a first horizontal position that the first robot arm base was in when the rotation of the first robot arm commenced in tandem with translation of the first robot arm base, and π=the numeric constant pi. It will be understood that while the rotation of the first robot arm 110 about the first axis 130 in tandem with movement of the first robot arm base 160 along the second axis 132 may be generally controlled according to the relationship discussed above, such movement may be modified to avoid sudden, step changes in direction for the wafer 112 (or the end effector). For example, the first robot arm 110 may be caused to start rotating relative to the first robot arm base 160 somewhat prior to, e.g., several centimeters before, the point where the center of the wafer 112 (if the wafer were to be present) would be directly before the target location 170 (such that the wafer 112 center would only need to move in a direction perpendicular to the second axis 132 in order to reach the location in the FOUP 106 where the wafer is to be placed in the FOUP 106 at that load port 104). Thus, instead of the wafer center traveling along the second axis 132 and then suddenly making a sharp, 90° change in direction in order to travel along an axis perpendicular to the second axis 132, such a transition may be controlled so that the wafer center avoids making a sharp, 90° turn and instead makes a soft 90° turn, e.g., follows a path in which there are two linear segments at 90° to each other that are joined by a curved or arcuate segment that is tangent to both linear segments.

Movements such as those discussed above may be used to cause the wafer 112, when supported by the end effector 164, to move straight out of the FOUP 106 within which it is positioned and in a direction perpendicular to the second axis 132 while the first robot arm base 160 moves along the second axis 132. The above-discussed movement provides for a system in which the wafer 112 only travels along straight lines, e.g., along the second axis 132 or in a direction perpendicular thereto. It will be appreciated, however, that the controller may control the motion of the first robot arm 110 and the first robot arm base 160 such that the wafer 112 follows a more efficient, smooth path, e.g., one that curves after it exits a FOUP 106 or load lock 108, thereby “cutting” the sharp corner that an orthogonal movement path may have. Such a curved path may present an overall shorter transit distance and may thus be more efficient in terms of maximizing wafer transfer speed. Such curved paths may also avoid sharp changes in acceleration direction, thereby reducing the risk of wafer slippage. In FIG. 1A, the heavy solid line that starts at the center of the second FOUP 106 from the left and terminates in the right-hand load lock 108 represents one such curved motion path for a wafer carried by the first robot arm 110. The path is nominally straight/perpendicular to the second axis 132 (and the rotational movement of the first robot arm 110 would thus follow the function noted above) at least until the wafer center has crossed the bolts plane, at which point the wafer center may follow a curved or arcuate path until it reaches the midpoint between the bolts plane 124 and the load lock plane 126. At this stage, the wafer center may again follow a nominally linear path, but this time one that is parallel to the second axis 132. The first robot arm base 160 may then be caused to reverse directions and the first robot arm may be caused to rotate towards the load locks 108, thereby being caused to follow another curving path. When the wafer center point crosses the load lock plane, the movement of the wafer may be caused to follow a straight line that is perpendicular to the second axis 132 until the wafer is correctly positioned within the load lock. Such movements may also be reversed in order to perform a wafer transfer in the opposite direction.

By coordinating the movement of the first robot arm base 160 and the first robot arm 110 in such a manner, or in a similar manner, it is possible to move the wafer 112 to a position that is fully within the wafer transit corridor “B,” thereby allowing the wafer to be moved between a plurality of locations along the second axis 132 and within the EFEM enclosure 102. Similar movements may then be performed in reverse in order to place the wafer 112 into any of the other FOUPs 106 or into either of the load locks 108. For example, FIGS. 1A through 1F show movements of the first robot arm 110 and the first robot arm base 160 during transfer of the wafer 112 from the left-most FOUP 106 to the left-most load lock 108.

In some cases, such as if the wafer 112 were to be placed into the right-most FOUP 106, the first robot arm 110 must first be caused to undergo a reversal in direction, e.g., instead of extending out to the left of the first robot arm base 160, the first robot arm 110 must be caused to extend out to the right of the first robot arm base 160. This is because the EFEM enclosure 102 in this example is not long enough to allow the first robot arm base 160 to move to the right of the rightmost FOUP 106, as would be required in order to position the wafer 112 within the rightmost FOUP 106 while the first robot arm 110 is extended to the left of the first robot arm base 160.

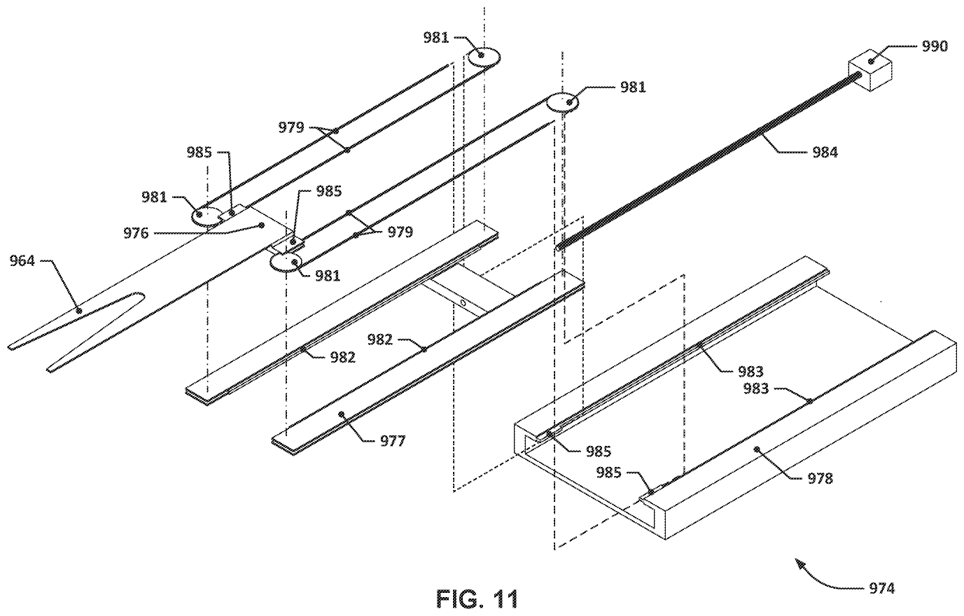

For example, in order to perform such a reversal in the directionality of the first robot arm 110 from the configuration shown in FIGS. 1A through 1K, the controller may cause the first robot arm base 160 to move to the right while causing the first robot arm 110 to rotate in a clockwise manner until the wafer 112 is fully within the wafer transit corridor “B,” as shown in FIGS. 1A through 1C. The controller may then cause the first robot arm base to 160 to continue moving to the right, e.g., until the wafer 112 is positioned directly in front of the entrance to one of the middle two FOUPs 106 or one of the two load locks 108, as shown in FIG. 1D. The first robot arm base 160 may then be caused to reverse direction, e.g., to the left, while the first robot arm 110 is caused to rotate from its position centered in the wafer transit corridor such that the wafer 112 moves in a direction perpendicular to the second axis 132 while the first robot arm base 160 moves along the second axis 132, as shown in FIGS. 1E and 1F, for example. The controller may cause the first robot arm base 160 to continue to move to the left after the first robot arm 110 has extended itself into the FOUP 106 or the load lock 108 as far as is possible (this technique may require that the destination in the FOUP 106 or the load lock 108 be empty of a wafer). The controller may similarly cause the first robot arm 110 to also rotate in a counterclockwise direction in tandem with such movement, as shown in FIGS. 1G and 1H. This simultaneous movement of the first robot arm base 160 and rotation of the first robot arm 110 may thus act to move the wafer 112, and the first robot arm 110, back into the wafer transit corridor—although this time with the direction of the first robot arm 110 reversed (pointing to the right), thereby allowing the first robot arm 110 to be used to place the wafer 112 into the right-most FOUP 106, as shown in FIGS. 11 through 1K. Thus, the single-link first robot arm 110 may be used to pick or place wafers in any of the FOUPs 106, although the first robot arm 110 may need to perform a “Y” turn for some pick or place operations depending on which FOUP is to be picked from or placed in. The first robot arm 110 may also be caused to undergo such direction reversals when not carrying the wafer 112.

In the EFEM enclosure 102 of FIGS. 1A through 1K, the EFEM enclosure 102 is designed to not protrude beyond the ends of the outermost load ports 104, thereby presenting an EFEM structure that is generally as compact as possible in terms of footprint. Such compactness, however, requires that the first robot arm 110 undergo the above-discussed Y-turn operations in order to reverse the extension direction thereof using one of the FOUPs 106 or the load locks 108 as a temporary “parking” position for the end effector 164 of the first robot arm 110 (and, if present, the wafer 112). This may not be the most desirable behavior for such a system since there may not always be such “parking” places available, e.g., there may be wafers in such locations that may block the use of such locations in such a manner.

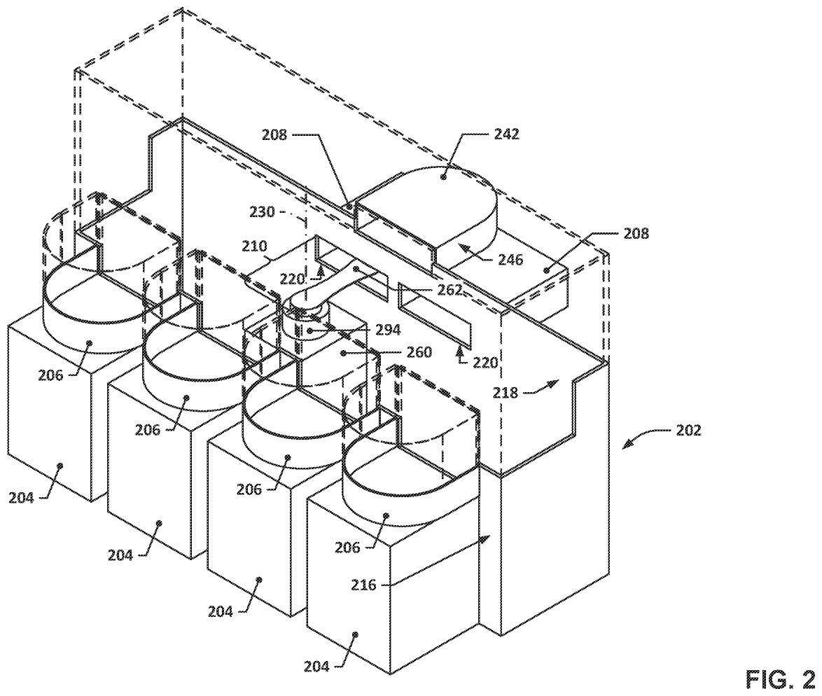

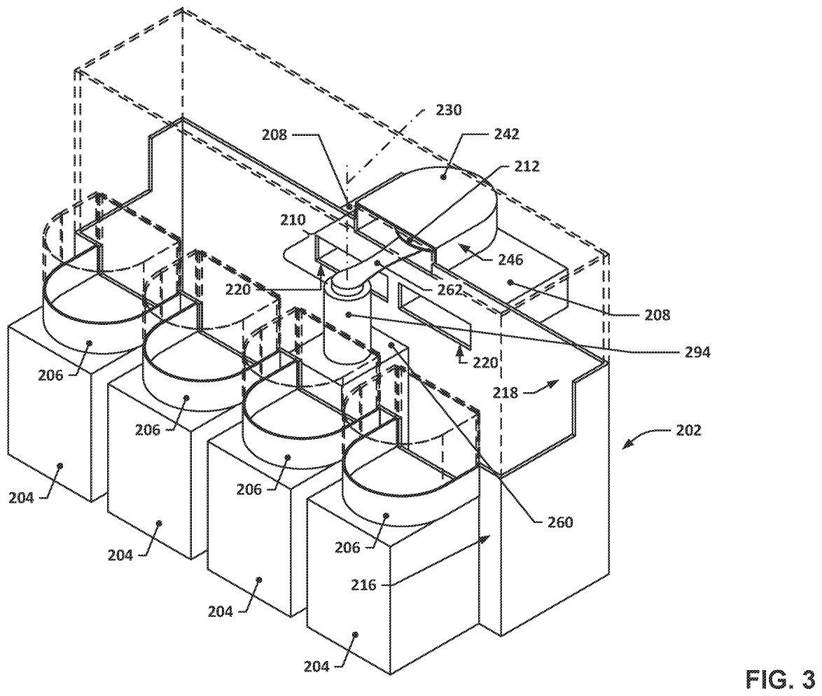

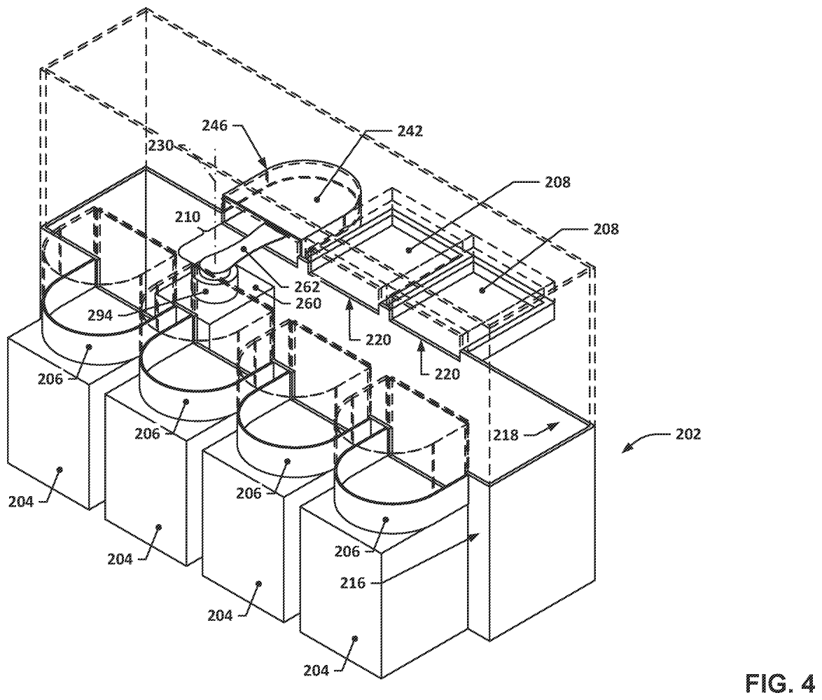

Alternate designs of such EFEM enclosures may be provided with a separate alcove or alcoves that may be located in the first wall 116 and/or the second wall 118 and which may be used as a “parking” spot for the end effector 164 (and, if present, wafer 112 that it supports) during a Y-turn. FIGS. 2 and 3, as well as FIG. 4, depict an example EFEM enclosure 202 that includes a first wall 216 and, opposite thereto, a second wall 218. In FIGS. 2 through 4, the top portion of the EFEM enclosure 202 (as well as other components that are shown) has been rendered as transparent and represented with broken lines to allow the interior of the EFEM enclosure 202 to be seen.

The first wall 216 has mounted thereagainst four load ports 204, each of which may support a FOUP 206 that may be placed thereupon. As with the EFEM enclosure 102, the EFEM enclosure 202 also includes within it a first robot arm 210 that is supported by a first robot arm base 260. The first robot arm 210, which has a first robot arm link 262 with an end effector (not visible, but see similar first robot arm link 162) is rotatably mounted to a turret 294 that may extend from the top of the first robot arm base 260 and which may be movable along a vertical axis relative to the first robot arm base 260 through action of a second linear translation system (not shown here, but discussed in a later portion of this disclosure) located within the first robot arm base. The turret 294 may house a rotational drive motor that may be controlled to cause the first robot arm 210 to rotate about a first axis 230 relative to the first robot arm base 260.

As can be seen in FIGS. 2 and 3, the second wall 218 of the EFEM enclosure 202 includes two load lock openings 220, each of which leads to a corresponding load lock 208. For the most part, these features are generally similar to the corresponding elements discussed above with respect to FIGS. 1A through 1K. The implementation of FIGS. 2 and 3, however, also includes an alcove 242 that is positioned above the load lock openings 220. The alcove may also alternatively be placed below the load lock openings 220, if desired. In either case, the alcove 242 may provide a temporary “parking” spot for the first robot arm 210 and, if supported thereby, a wafer during a Y-turn so that the Y-turn may be accomplished without requiring that the first robot arm 210 (and wafer, if present) be moved into one of the load locks 208 or one of the FOUPs 206 during the Y-turn. The vertical translation capability of the turret 294 may be used to move the first robot arm along a vertical axis and between at least a first vertical position and a second vertical position. In the first vertical position, the end of the first robot arm 210 that is furthest from the first axis 230 may be at an elevation that is within a first elevation range spanned by at least one of the load lock openings 220, thereby allowing the first robot arm 210 to be inserted into the load locks 208. In the second vertical position, the end of the first robot arm 210 furthest from the first axis 230 may be at an elevation that is within a second elevation range occupied by the alcoves 242. FIG. 2 shows the first robot arm 210 in the first vertical position, while FIG. 3 shows the first robot arm 210 in the second vertical position. It will be appreciated that the controller of an EFEM such as that shown in FIGS. 2 and 3 may, when a reversal of the directionality of the first robot arm 210 is needed, control the vertical drive mechanism within the first robot arm base 260 to cause the turret 294 to elevate so that the first robot arm 210 is in the second vertical location, at which point the first robot arm base 260 and the first robot arm 210 may be caused to translate and rotate, respectively, to cause the first robot arm 210 to be inserted into, and then removed from, the alcove in order to allow the first robot arm base 260 to transit in front of the alcove 242 and thereby switch which side of the first robot arm base 260 the first robot arm 210 is located on. Once the direction of the first robot arm 210 has been reversed, the vertical drive mechanism may be again actuated so as to cause the turret 294 to descend so that the first robot arm 210 is at the first vertical location. This allows the first robot arm 210 to pick and/or place wafers into the FOUPs 206 and/or the load locks 208.

FIG. 4 depicts a similar implementation, except that the alcove 242 is located to the side of the load locks 208, e.g., to the left side (the right side, or both sides, is also possible). It will be observed that the EFEM enclosure 202 in FIG. 4 is somewhat longer on the left side; this provides extra clearance to allow the first robot arm base 260 to move far enough to the left that the first robot arm 210 can, while supporting a wafer (not shown) be moved into, or out of, the alcove 242 from either direction, thereby allowing the directionality of the first robot arm 210 to be reversed as needed.

The alcoves 242 may generally have interior surfaces that define a space that is large enough to receive, without contact between the wafer and first robot arm 210 and the alcove 242, both the first robot arm 210 and a wafer supported thereby at the full extension length of the first robot arm 210 in a direction perpendicular to the second axis (not shown, but the long axis of the EFEM enclosure 202). For example, each alcove 242 may have an interior surface that faces towards the first wall 216 that is at least as far from a reference plane that is coincident with the first axis 230 and parallel to the load lock plane defined by the load locks 208 (see previous discussion of the load lock plane of FIGS. 1A through 1K) as the end of the first robot arm 210 that is furthest from the first axis 230 is from the first axis 230, and the alcove 242 may, as discussed earlier, be sized large enough that an end of the first robot arm 210 furthest from the first axis 230 is insertable into the alcove 242 without coming into contact with walls 246 defining that alcove 242 when the first robot arm 210 is extended such that the end of the first robot arm 210 furthest from the first axis 230 is also furthest from the first wall 216.

It will be noted that for implementations in which an alcove 242 is located in the first wall 216, such an alcove 242 may generally not be positioned above or below a load port 204—the spaces below the load ports 204 are occupied by FOUP door opening mechanisms and thus not available for housing an alcove, and the spaces above the load ports 204 are reserved as transit corridors for FOUPs 206 that are lowered onto, or lifted vertically off of, the load ports 204 by an overhead transport system. Thus, in implementations in which an alcove or alcoves 242 are located in the first wall 216, such alcoves 242 may be located to the left or right of, or in between, load ports 204. For example, instead of multiple load ports 204 being provided in an equally spaced manner, such load ports 204 positioned such that some load ports are spaced farther apart than others, thereby leaving a gap large enough to allow an alcove or alcoves to be positioned in between two adjacent load ports.

The previously discussed implementations feature EFEM enclosures that do not protrude, or protrude only about half a wafer diameter, past either of the endmost load ports. In such implementations, there may be a need to have the first robot arm perform Y-turns in order to reach some pick and/or place locations, as discussed above. Other implementations, however, may feature EFEM enclosures that extend beyond one or both outermost load ports, e.g., sufficiently far enough to allow the first robot bases thereof to travel into the extension regions by a distance sufficient to allow the first robot arms thereof to be rotated so as to be inserted into a FOUP supported by the load port closest thereto. Such EFEM configurations may allow the first robot arms thereof to access all of the load locks and/or FOUPs without requiring any reversal of direction of the first robot arm along the translation axis of the first robot arm base.

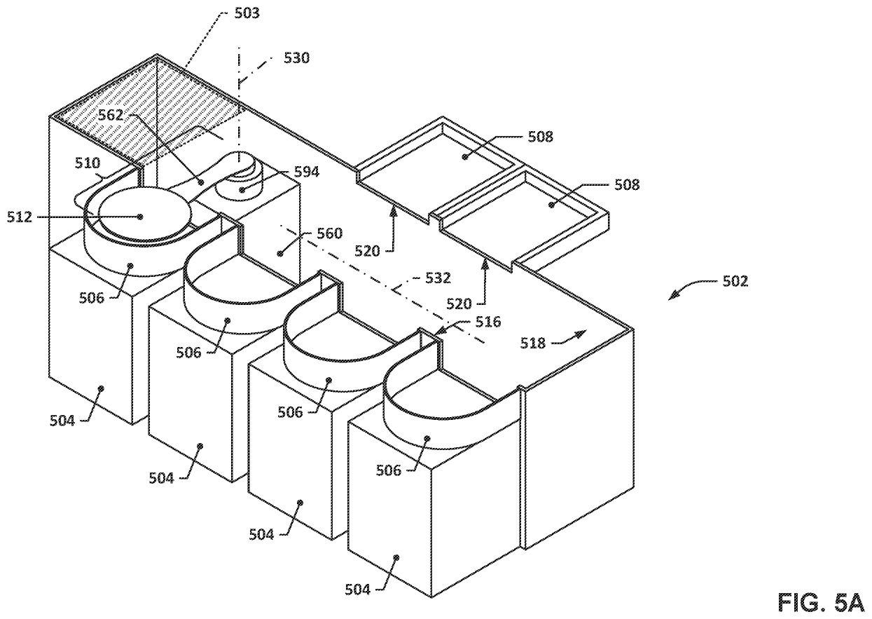

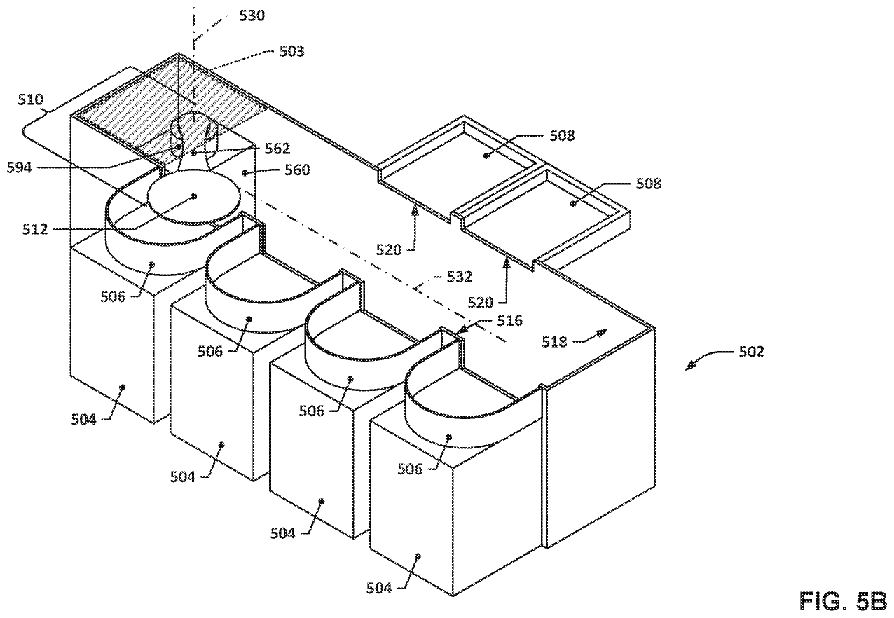

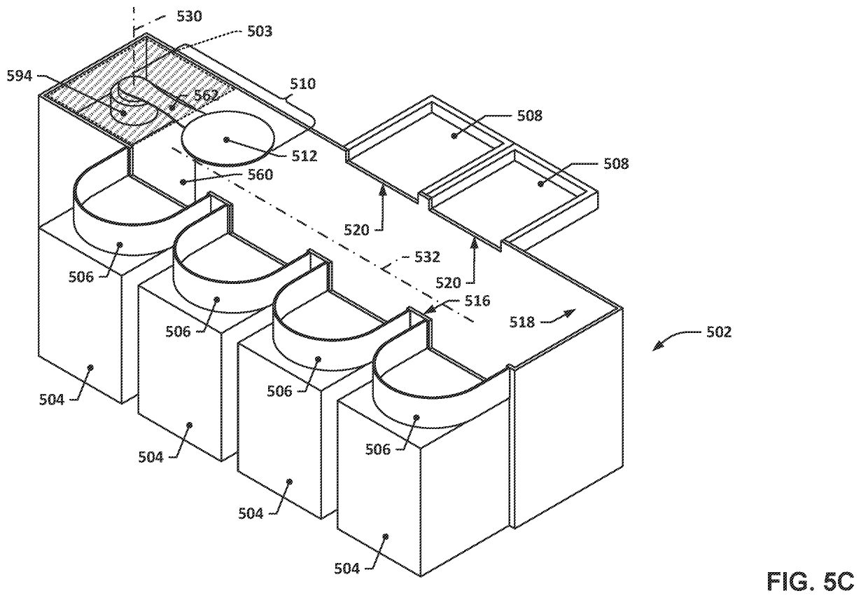

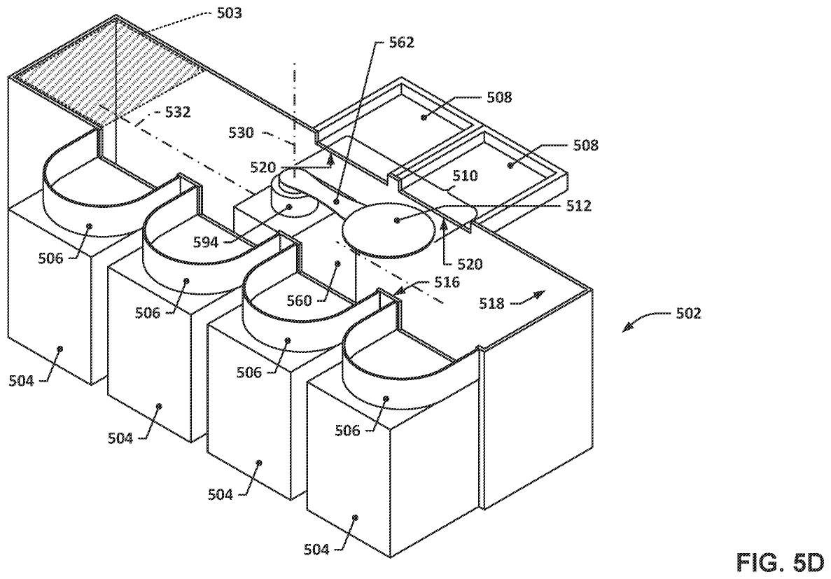

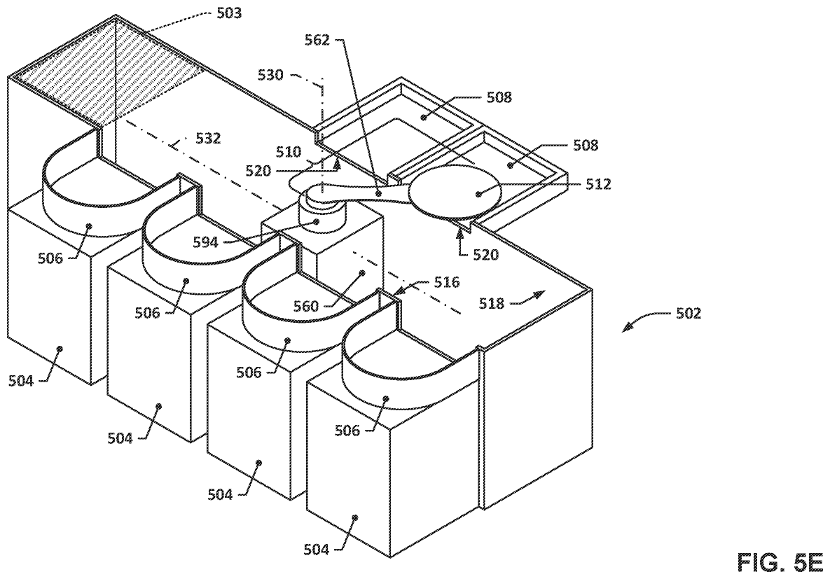

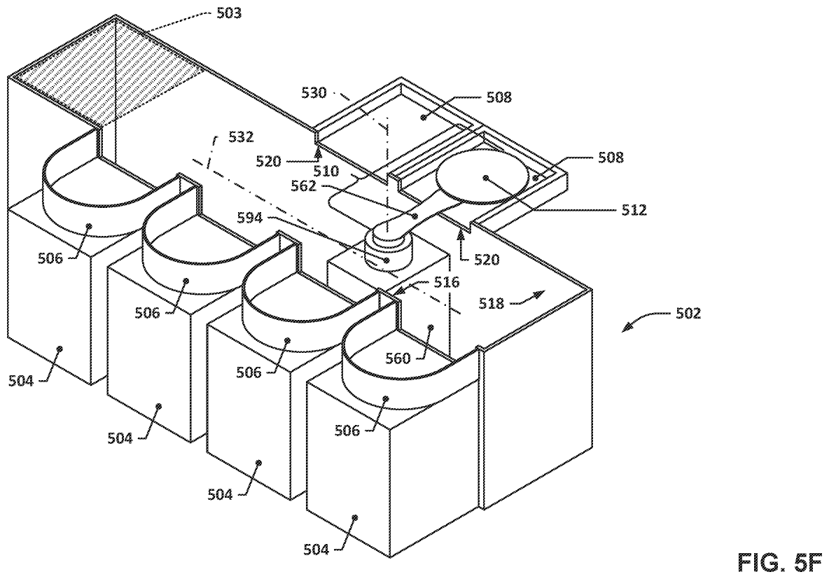

FIGS. 5A through 5F depict views of an EFEM enclosure 502 during various stages of operation. The EFEM enclosure 502 is, as with previous examples discussed herein, interfaced with a series of load ports 504 located along a first wall 516 thereof. Two load locks 508 are interfaced with a second wall 518 opposite the first wall. A first robot arm 510 may be rotatably coupled with a turret 594 of a first robot arm base 560. The first robot arm 510 may have a first robot arm link 562 that may be used to support a wafer 512. A rotational drive within the turret 594 may be controllable to cause the first robot arm 510 to rotate relative to the first robot arm base 560 and about a first axis 530. A vertical translation system (not shown) within the first robot arm base 560 may be configured to raise or lower the turret 594, thereby allowing the elevation of the first robot arm 510 to be adjusted. A first linear translation system (not shown but see the first linear translation system 156 discussed earlier) may be controlled to cause the first robot arm base 560 to translate along a second axis 532 within the EFEM enclosure 502.

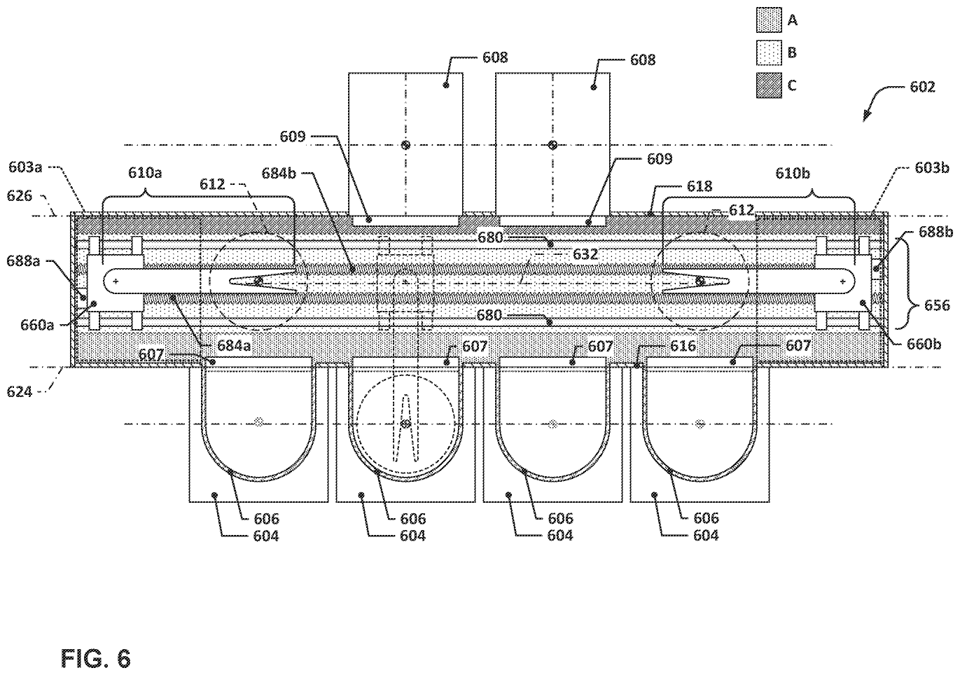

The EFEM enclosure 502 in this example features an extension region 503 that extends the EFEM enclosure 502 past the left-most load port 504. The first linear translation system may extend into the extension region 503 so that the first robot arm base 560 may be translated into the extension region 503 in order to allow access by the first robot arm 510 to any of the FOUPs 506 without requiring reversing the side of the first robot arm base 560 that the first robot arm 510 extends from. The extension region 503 may, for some implementations, protrude beyond the edge of the closest load port 540 by at least the wafer diameter D (if multiple extension regions are included in an EFEM enclosure, as discussed later with respect to FIG. 6, each such extension region may extend beyond the load port closest thereto and along the second axis by a distance of at least the wafer diameter D).

As can be seen in FIGS. 5A through 5C, by moving the first robot arm base 560 to the left and rotating the first robot arm 510 counterclockwise about the first axis 530, the end of the first robot arm 510 supporting the wafer 512 may be caused to move out of the left-most FOUP 506 and into the wafer transit corridor (see FIG. 1A). It will be appreciated that the reverse of such movements may also be used to cause the first robot arm 510 to be inserted into the left-most FOUP 506, e.g., to reach the configuration shown in FIG. 5A.

It will be appreciated that the first robot arm 510 may be caused to remove a wafer 512 from any of the FOUPs 506 in a similar manner. For example, the first robot arm 510 may (starting from the configuration shown in FIG. 5C) be moved to the right so as to position the end effector thereof in front of any one of the FOUPs 506 and the first robot arm 510 then rotated clockwise during further right-wise movement, thereby causing the first robot arm 510 to be inserted into the desired FOUP 506.

Similar movements may be taken on the opposite side of the EFEM enclosure 502 in order to pick or place wafers from or into the load locks 508, as shown in FIGS. 5D through 5F. For example, in FIG. 5D, the first robot arm base 560 has been moved to the right along the second axis 532 such that the wafer 512 is positioned directly in front of the load lock opening 520 leading to the right-hand load lock 508. In FIG. 5E, the first robot arm base 560 has been caused to move further to the right while the first robot arm 510 is simultaneously caused to rotate counterclockwise, thereby causing the wafer 512 to move into the right-hand load lock 508. In FIG. 5F, the first robot arm base 560 has moved further to the right, thereby causing the first robot arm 510 to extend to its furthest possible extent into the right-hand load lock 508.

In implementations such as that shown in FIGS. 5A through 5F, the first linear translation system may be configured to provide the first robot arm base 560 with a linear travel distance of at least X+D, i.e., the travel distance provided by the first linear translation system may be at least the distance between target locations of the two outermost FOUPs 506 plus the diameter of the wafer. Such a configuration allows room for the first robot arm base 560 to be able to move far enough to the left to allow the wafer 512 to be positioned relative to the left-most FOUP such that when the first robot arm base 560 is caused to move to the right while the first robot arm 510 is caused to rotated towards the FOUPs 506, the first robot arm 510, and any wafer 512 supported thereby, is able to be swung into that left-most FOUP 506.

In the implementations discussed herein, robot arms like the first robot arm 510 may also be caused to translate vertically upward or downward by a small distance, e.g., by actuating the vertical translation system in the first robot arm base, when picking or placing wafers from or into the FOUPs 506 and/or the load locks 508. For example, FOUPs generally include a large number of ledges, e.g., 25, that extend inward from the outer walls of the FOUP. Such ledges may be sized such that a wafer that is placed within the FOUP is able to be located such that the wafer overlaps with the ledges immediately below it when viewed from above. The overlapping regions of the wafer may thus rest on the ledge(s) immediately below the wafer, thereby allowing the wafer to be supported within the FOUP. Loadlocks may similarly have an interior ledge or ledges, or may have other structures located within them, e.g., pins, that the wafer may be lowered onto or raised up off of during place or pick operations, respectively. In some implementations, the load lock 508 may include a lift pin mechanism that may lift the wafer off of, or lower the wafer onto, the first robot arm 510 without requiring vertical movement of the first robot arm 510.

It will also be understood that while the implementation of FIGS. 5A through 5F demonstrates a particular handedness, e.g., with the extension region 503 on the left of the EFEM enclosure 502 in the Figures, other implementations with the handedness reversed, e.g., with the extension region 503 on the right of the EFEM enclosure 502 are also contemplated. Thus, the mirror image of what is shown in FIGS. 5 through 5F is also within the scope of this disclosure. This will similarly be understood to apply to other example implementations discussed herein that exhibit a “handedness,” e.g., that exhibit left/right asymmetry.

The movement of the first robot arm in the above-discussed examples may generally be broken into two different types of movement. In the first type of movement, the first robot arm base may be moved along the second axis with the first robot arm in a first rotational position that causes it to lie entirely in between the bolt plane and the load lock plane and, in some implementations, entirely within the wafer transit corridor. In some such movement, the first robot arm may be kept stationary with respect to the first robot arm base. In the second type of movement, the first robot arm base may be translated along the second axis while the first robot arm is simultaneously caused to rotate from the first rotational position, about the first axis, and to a second rotational position in which the first robot arm extends through the bolt plane or through the load lock plane.

A further implementation of the EFEM enclosure with extension region of FIG. 5A is depicted in FIG. 6. In FIG. 6, an EFEM enclosure 602 is shown that includes extension regions 603a and 603b. The EFEM enclosure 602 may have a first wall 616 that defines a bolt plane 624 that has interfaced thereto a plurality of load ports 604 that may be configured to support a plurality of FOUPs 606. Removable FOUP doors 607 may provide access to the interiors of the FOUPs 606. The EFEM enclosure 602 may also include a second wall 618 that has interfaced thereto one or more load locks 608. The load locks may be sealed with load lock doors 609, which may be caused to open during wafer loading or unloading.

Such an arrangement may allow for two robot arms, e.g., first robot arm 610a and second robot arm 610b, to be housed within the EFEM enclosure 602. A first linear translation system 656 may be provided that may feature first linear guides 680 that may support both a first robot arm base 660a and a second robot arm base 660b such that both robot arm bases are able to translate horizontally along the first linear guides 680. The first linear translation system 656 may include a first drive screw 684a and a second linear screw 684b, each of which may be independently driven by a corresponding first drive motor 688a and second drive motor 688b, respectively.

The first robot arm 610a may be supported by the first robot arm base 660a and may be caused to translate along the first linear guides 680 through actuation of the first drive screw 684a by first drive motor 688a. The second robot arm 610b may similarly be supported by the second robot arm base 660b and may be caused to translate along the first linear guides 680 through actuation of the second drive screw 684b by a second drive motor 688b. The first drive screw 684a may be configured to engage with a threaded nut that is part of the first robot arm base 660a but not engage with the second robot arm base 660b while the second drive screw 684b may be configured to not engage with the first robot arm base 660a but engage with a threaded nut that is part of the second robot arm base 660b. Thus, the first drive screw 684a and the second drive screw 684b may be used to separately and independently cause the first robot arm base 660a and the second robot arm base 660b, respectively, to travel along the second axis 632. This allows, for example, the first robot arm 610a to be able to pick or place wafers 612 from or into both load locks 608 and all but the rightmost FOUP 606, while the second robot arm 610b is able to pick or place wafers 612 from or into both the load locks 608 and all but the left-most FOUP 606. For example, either the first robot arm 610a or the second robot arm 610b may be positioned in the location shown with a dotted outline of a robot arm in order to pick or place a wafer 612 from or into the FOUP 606 second from the left. Such an arrangement may provide higher throughput than may be available with other EFEMS discussed earlier herein, as two wafers 612 may be transported simultaneously by the two robot arms.

As discussed earlier, shallow-depth EFEMs may also be equipped with multiple-link robot arms. Such arms, while more complicated than single-link robot arms, may be used to similar effect and may provide for an expanded range of motions that allow such robot arms to navigate more efficiently within the EFEM.

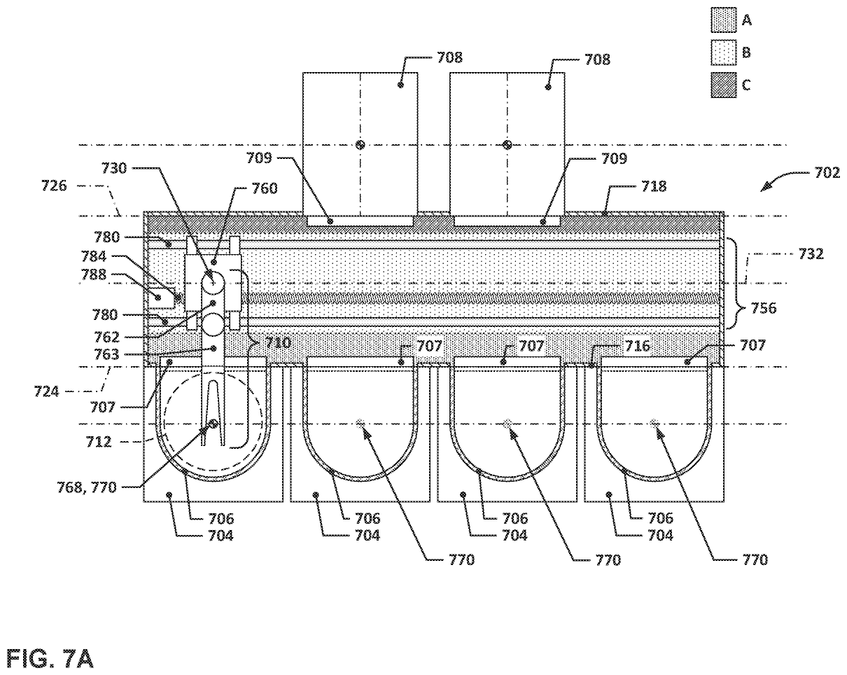

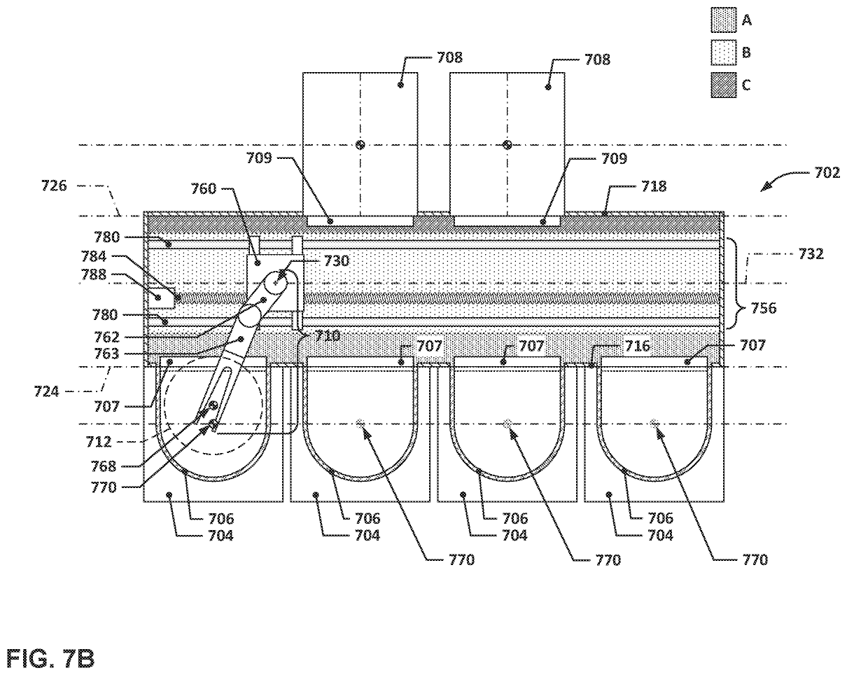

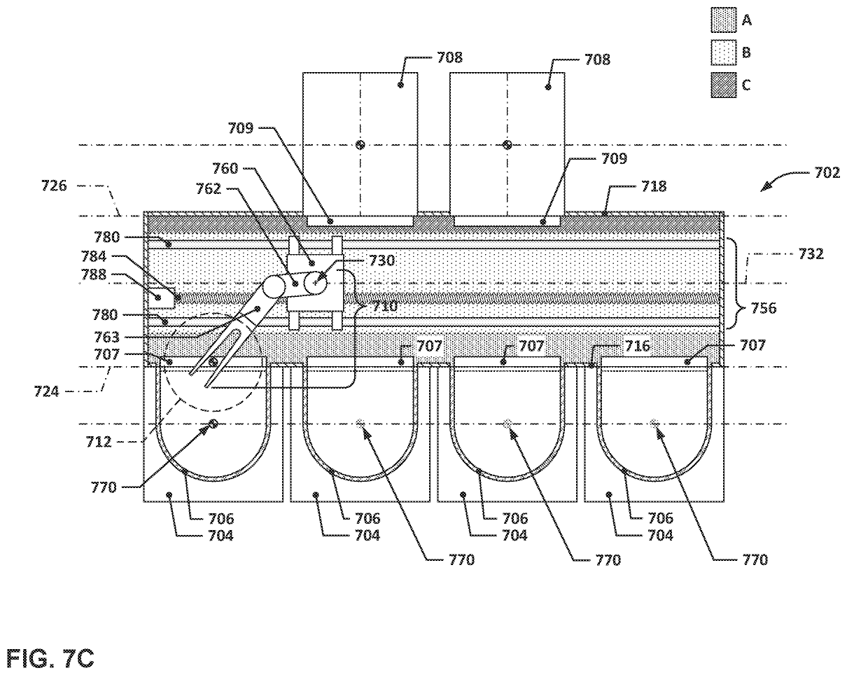

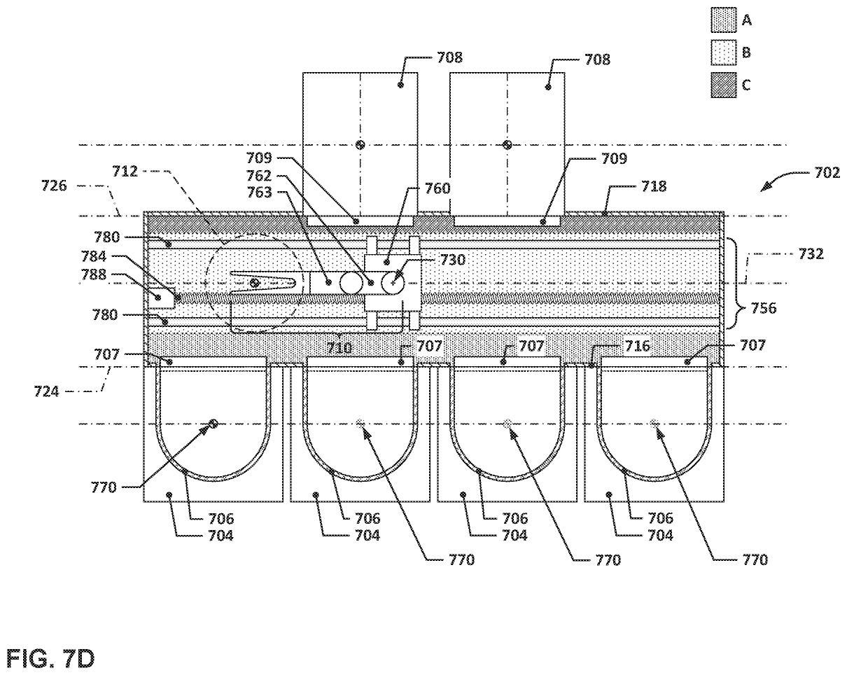

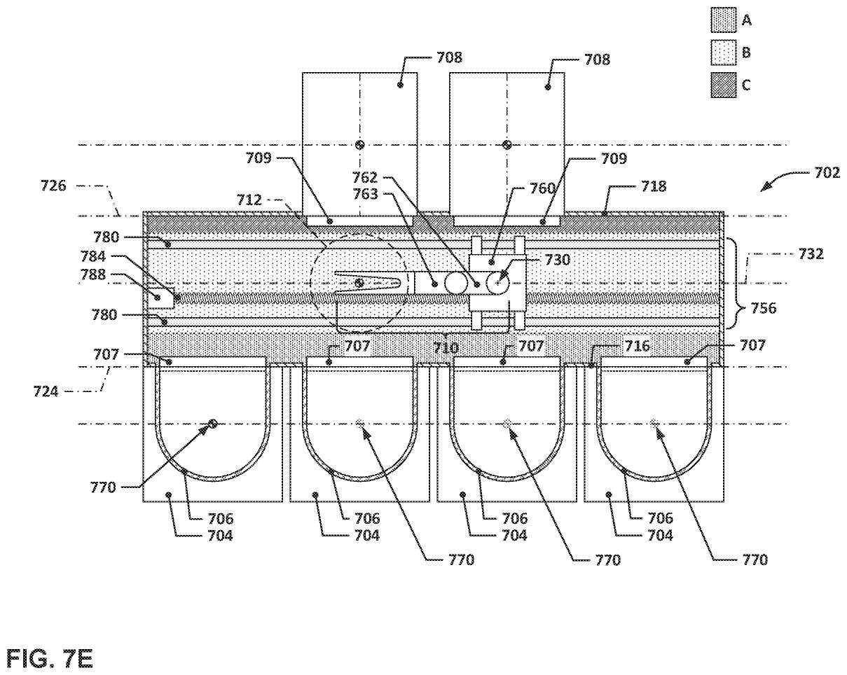

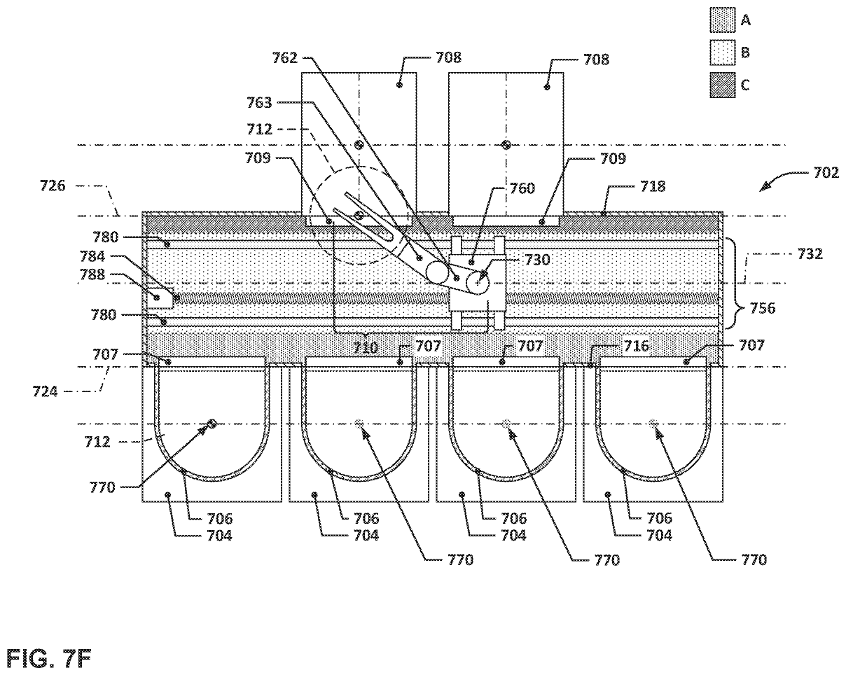

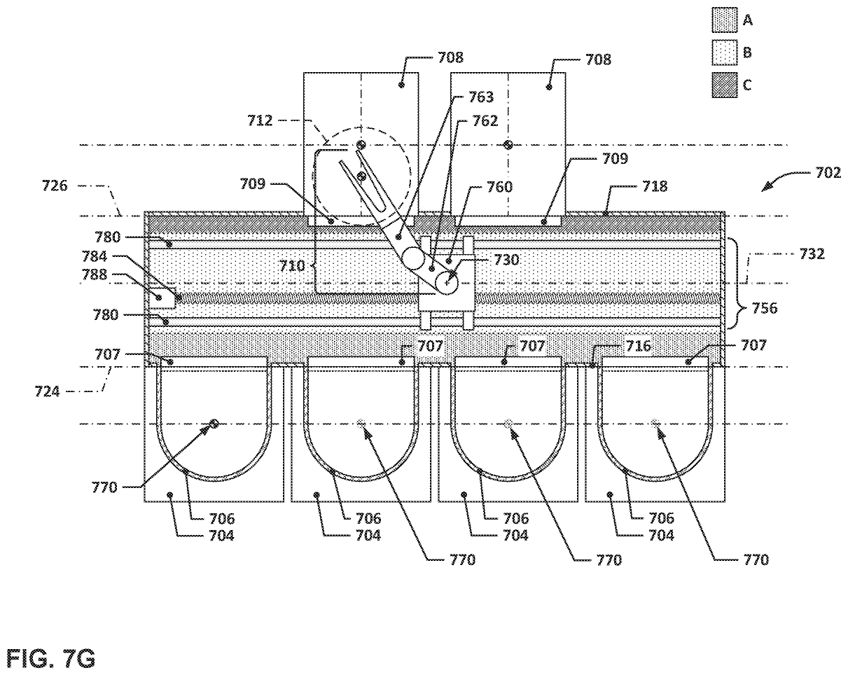

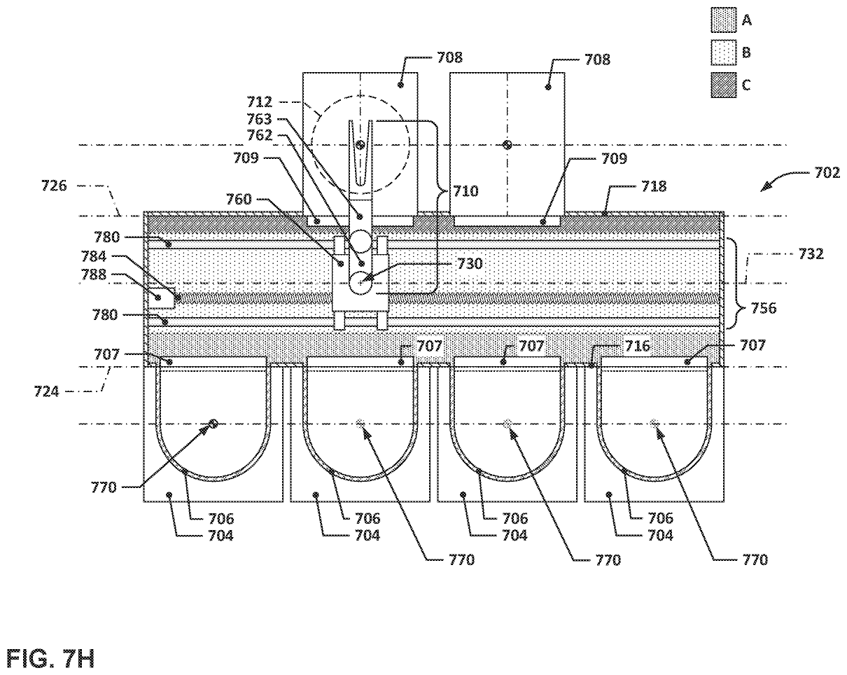

FIGS. 7A through 7H depict an example implementation of a shallow-depth EFEM having a multiple-link robot arm during various stages of operation, e.g., in locations and configurations that such a robot arm would be in when transporting a wafer from the left-most FOUP 706 to the left load lock 708. The elements shown in FIGS. 7A through 7H are, in many cases, the same as similarly appearing elements of FIGS. 1A through 1K. Such elements in FIGS. 7A through 7H have the same last two digits of their callouts as in FIGS. 1A through 1K, and it will be understood that the description provided earlier with reference to FIGS. 1A through 1K is equally applicable to the corresponding elements in FIGS. 7A through 7H unless indicated otherwise. Separate or repeat description of such elements is avoided here in the interest of brevity.

As seen in FIGS. 7A through 7H, the first robot arm 710 includes a first robot arm link 762 and a second robot arm link 763 that terminates in a first end effector. The first robot arm link 762 may be rotatably coupled at one end to the first robot arm base 760 so that it is rotatable about the first axis 730 relative to the first robot arm base 760. The second robot arm link 763 may be rotatably coupled at the end opposite the first end effector with the first robot arm link 762 so that it is rotatable about an elbow axis relative to the first robot arm link 762. The first robot arm 710 may be configured such that rotation of the first robot arm link 762 relative to the base 760 and rotation of the second robot arm link 763 relative to the first robot arm link 762 may occur independently.

Such an arrangement may allow the first robot arm 710 to potentially navigate around corners more effectively, e.g., corners associated with the entrances to load ports 704/FOUPs 706 and/or load locks 708. For example, as can be seen in FIG. 7G, when the first robot arm 710 is being caused to reach into one of the load locks 708, a single-link robot arm (see FIG. 1E) may come very close to, or potentially interfere with (depending on the particular layout of the EFEM), other hardware that is inside, attached to, or part of the EFEM 702.

In FIG. 1E, for example, it can be seen that the first robot arm 110 is extremely close to the right front corner of the load lock 108 on the left (and if there is hardware in the clearance zone “C” in between the two load locks 108, then there would be even less clearance between that hardware and the first robot arm 110).

In FIG. 7G, however, the first robot arm 710 has been controlled so as to bend in between the first robot arm link 762 and the second robot arm link 763 so as to provide additional clearance between the first robot arm link 762 and the second robot arm link 763 and the right-side front corner of the left-most load lock 708. This may help ensure that no collisions occur between the first robot arm 710 and, for example, the second wall 718, the load lock 708, or any equipment in the clearance zone “C.”

It will be noted that the first robot arm 710 may, in general, be used in a similar fashion to the first robot arm 110 with respect to retrieving or placing wafers 712. In situations in which the first robot arm 710 is caused to rotate from a position in which the target location 768 is centered on the second axis 732, the first robot arm 710 may, in some such cases, be controlled so as to cause the second robot arm link 763 to rotate relative to the first robot arm link 762 prior to, or at the same time as (and in the same direction as), rotation of the first robot arm link 762 relative to the first robot arm base 760, thereby causing the initial rotational movement of the first end effector to be about a smaller radius and thus allowing it to navigate a more constrained motion path.

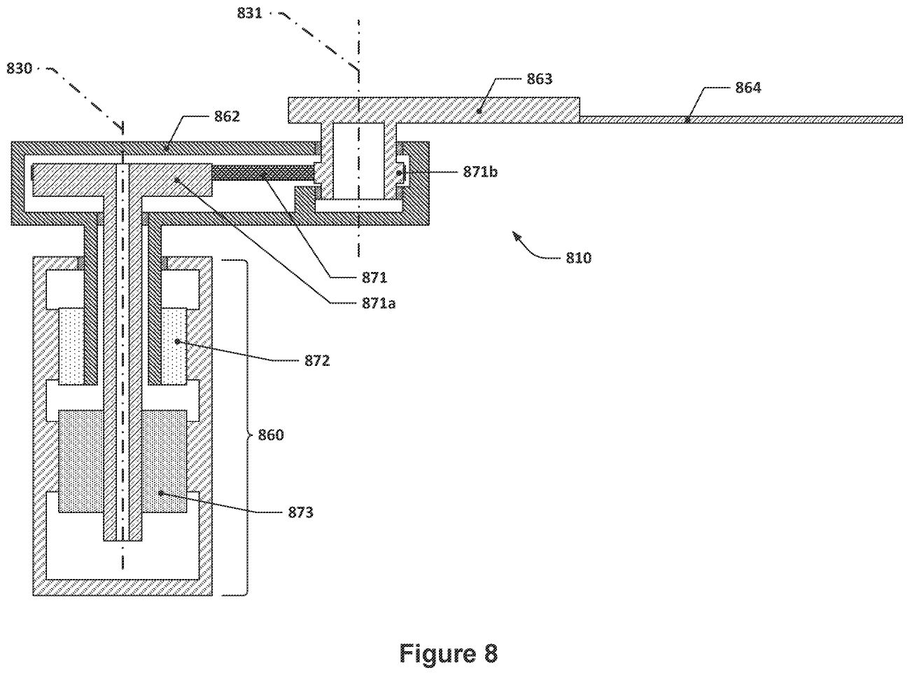

FIG. 8 depicts a side section view of an example multiple-link robot arm. In FIG. 8, a first robot arm 810 is supported by a first robot arm base 860 that includes an arm rotation motor 872 and an elbow rotation motor 873. The arm rotation motor 872 may have a rotational output that is coupled to a first robot arm link 862 such that when the arm rotation motor 872 is actuated to cause its rotational output to rotate, the first robot arm link 862 rotates about a first axis 830 as well. The elbow rotation motor 873 may similarly have a rotational output that is coupled to a pulley 871a, which may, for example, be located at the end of a shaft that passes through, and is coaxial with, a tube that supports the first robot arm link and is coupled to the arm rotation motor 872's rotational output. The pulley 871a may be kinematically coupled to a pulley 871b via a belt 871. The pulleys 871a and 871b may both be rotationally mounted with respect to the first robot arm link 862 such that when either pulley 871a or 871b is caused to rotate relative to the first robot arm link 862, the other of the pulleys 871a and 871b also rotates relative to the first robot arm link 862. Thus, when there is relative rotation between the rotational outputs of the arm rotation motor 872 and the elbow rotation motor 873, this causes the second robot arm link 863 to rotate relative to the first robot arm link 862 about elbow axis 831. When there is no relative rotation between the rotational output of the arm rotation motor 872 and the elbow rotation motor 873 (i.e, they are both stationary or rotating at the same speed and in the same direction), this causes the second robot arm link 863 to rotate with the first robot arm link 862 but with no relative rotation between them.

In other implementations, the elbow rotation motor 873 may instead be located within the first robot arm link 862 or the second robot arm link 863, thereby avoiding the potential need for the belt 871 or similar motion transfer system.

It will be noted that in shallow-depth EFEMs such as are described herein, multi-link arms that are used may be constrained to a particular subset of such multi-link arms, e.g., arms in which the robot arm link to which the end effector is attached has a first distance between the rotational axis of the rotational joint supporting that robot arm link and the target location of the end effector on which the wafer is to be centered that is longer than a second distance between the rotational axes of the rotational joints at either end of the robot arm link that supports that end-effector-arm-link relative to the first robot arm base. In some such implementations, for example, the first distance may be at least twice the second distance. In some such implementations, the second distance may be constrained to be less than the distance between a plane that is parallel to the first axis (along which the first robot arm base 860 is configured to translate) and parallel to and coincident with the first axis 830 and whichever is closest thereto of the first wall 816 and the second wall 818. In some such implementations in which the multi-link arm is a two-link arm (as shown in FIG. 8), the second distance may be further constrained to be less than one half of the diameter of the wafer, e.g., less than or equal to half the wafer diameter minus the amount by which that link extends past the elbow axis 831. Thus, for example, in the context of FIG. 7, such an robot arm link may be able to rotate a full 360° without swinging outside of the robot transit corridor “B” (or swinging only minimally outside of the robot transit corridor “B” but, at the same time, not colliding with the walls of the EFEM in front of each load port 804 or load lock 808).

As discussed earlier, some shallow-depth EFEMs may utilize a telescoping robot arm in place of the single-link rigid robot arms or multi-link robot arms discussed above. The telescoping robot arm that is used may be transitionable between a retracted state and an extended state. In some instances, the telescoping robot arm may include three or more portions that are configured to translate relative to one another and that are each sized so as to be no longer than the diameter of the wafer that such a robot arm is configured to transport. Such telescoping robot arms may, for example, allow the entire telescoping robot arm (when in the retracted state) to fit within the same movement envelope (when viewed from above) that is provided for movement of wafers transported thereby. In other words, if there is a movement envelope that is sufficiently wide for a wafer to transit therethrough, that same movement envelope would generally be wide enough for the telescoping robot to also transit therethrough when in the retracted state.

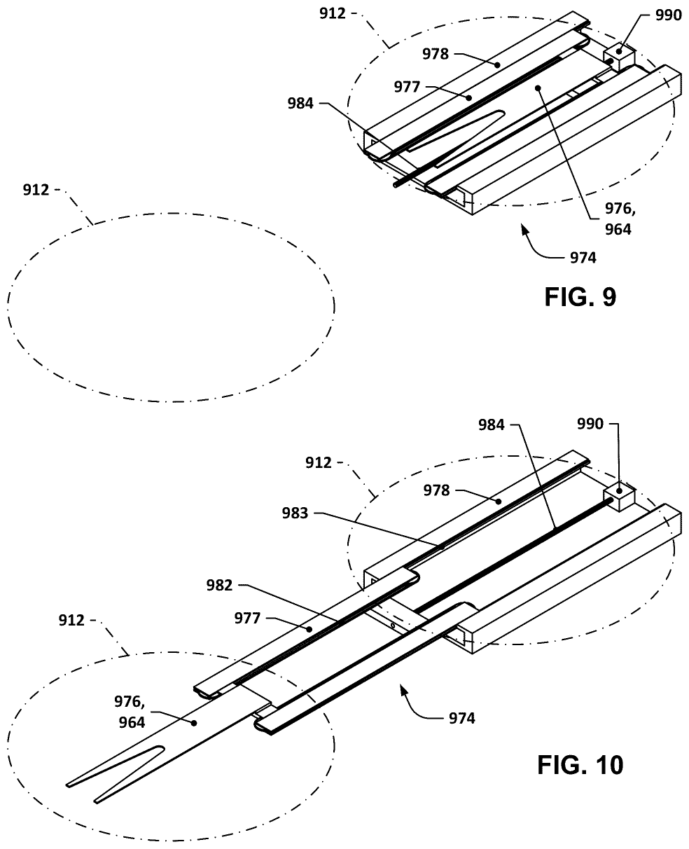

FIGS. 9 through 11 depict various views of an example telescoping robot arm; other approaches to telescoping robot arms may be used as well, and this disclosure is not intended to be limited to only the specific example. For example, the depicted telescoping robot arm uses a pulley/belt system to allow a single drive motor to drive the extension and retraction of the telescoping portions of the telescoping robot arm. However, an alternate approach could be to provide separate drive motors for each telescoping portion, or to use racks and pinion gears in place of pulleys and belts.

FIG. 9 shows a telescoping robot arm 974 in the retracted state, while FIG. 10 shows the telescoping robot arm 974 in the extended state. FIG. 11 shows the telescoping robot arm 974 in an exploded state.

As can be seen, the telescoping robot arm 974 has a first portion 976 that includes a first end effector 964, a second portion 977, and a third portion 978. The second portion 977 may be equipped with second linear guides 982 that may engage with mating features on the first portion 976 so as to allow the first portion 976 and the second portion 977 to translate along an extension axis relative to one another. The third portion 978 may similarly be equipped with third linear guides 983 that may engage with mating features on the second portion 977 so as to allow the second portion 977 and the third portion 978 to translate along the extension axis relative to one another. The third portion 978, it will be understood, may be fixedly mounted to a rotational interface, e.g., a turret, to allow the first portion 976, the second portion 977, and the third portion 978 to be rotated about a rotational axis as a unit.

The telescoping robot arm 974 may also include, for example, a second drive motor 990 that may be configured to rotate a first drive screw 984 about a rotational axis; the rotational axis may also serve as the extension axis. The second drive motor 990 may be fixedly mounted with respect to the third portion 978, and the first drive screw 984 may be threaded into a nut that is fixedly mounted (at least with respect to movement along the extension axis) with respect to the second portion 977. Thus, when the second drive motor 990 causes the first drive screw 984 to rotate, the second portion 977 may be caused to translate relative to the third portion 978, e.g., along the extension axis. This allows the second portion 977 to be transitioned from the position it is in relative to the third portion 978 in the extended state to the position it is in relative to the third portion 978 in the retracted state.

As shown perhaps most clearly in FIG. 11, the second portion 977 may also include a plurality of pulleys 981 that are rotatably mounted with respect to the second portion 977. For example, in the depicted example, the second portion 977 has two longitudinal members that extend along directions parallel to the extension axis and which are joined by a cross-member that contains the nut that engages with the first drive screw 984. The two longitudinal members may each have pulleys 981 located in opposing ends. The first portion 976 and the third portion 978 may also have anchor points 985. The anchor points 985 on the first portion 976 may be connected with the anchor points 985 on the third portion 978 by way of belts 979, e.g., thin, flexible, steel belts (or braided steel cables). For example, each pair of anchor points 985 ends facing the same direction on either side of the telescoping robot arm 974 may be connected together by a corresponding belt 979. In some implementations, the belts 979 on either side of the telescoping robot arm 974 may be provided as single belts 979 that are, for example, pinned in the middle to one of the anchor points 985.

The belts 979 may each be looped over one of the pulleys 981 such that when the second portion 977 is caused to extend outward from the third portion 978, the pulleys 981 at the end of the second portion 977 place the outermost belts 979 into tension. As the ends of the outermost belts 979 are, at one end, anchored to the anchor points 985 that are fixedly mounted with respect to the third portion 978, the tensioned outermost belts 979 will be drawn over the pulleys 981 that support them, thereby pulling the first portion 976 towards the end of the second portion 977 furthest from the third portion 978. During retraction, the same process may occur, but in reverse and using the innermost belts 979. Such an arrangement allows the telescoping robot arm 974 to have sufficient reach that it can transition wafers between the two wafer positions 912 shown in FIGS. 9 and 10 (e.g., by a distance that is sufficient to move the wafer into/out of a FOUP or load lock from the EFEM) while also being relatively thin, e.g., thin enough that the first portion 976 and at least part of the second portion 977 are able to pass through, for example, slit valves used to seal load locks or in between wafers that are loaded into a FOUP (such wafers are normally spaced apart vertically by 10 mm center-to-center).

It will be appreciated that other, similar telescoping arm designs may be used as well, e.g., including four portions, five portions, etc., and using a similar actuation mechanism.

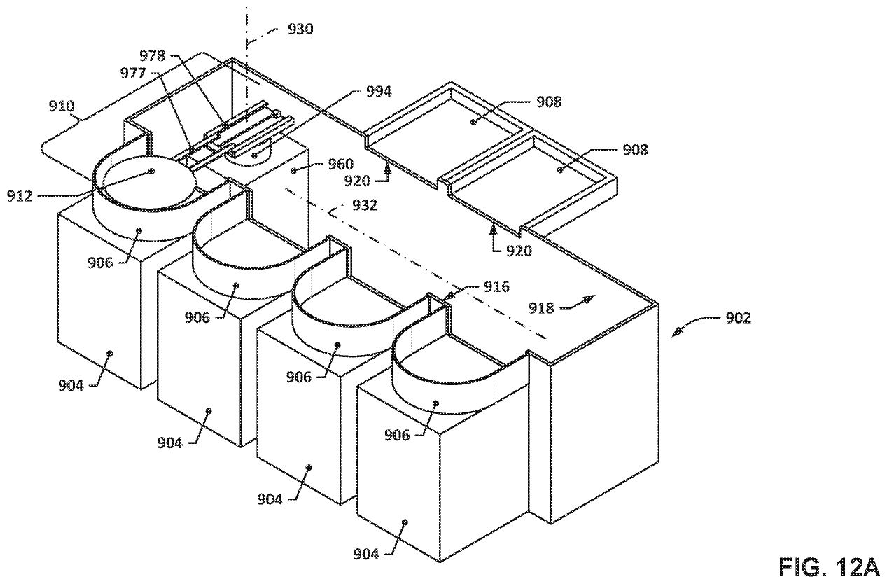

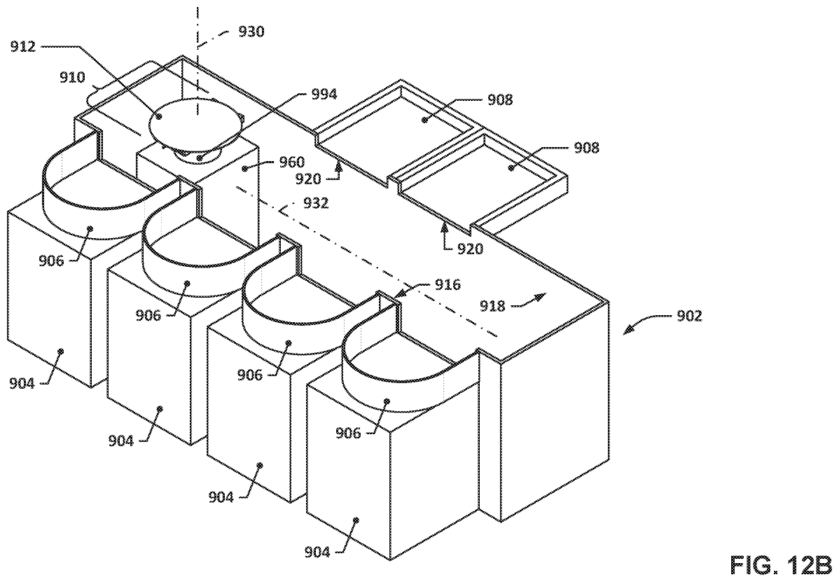

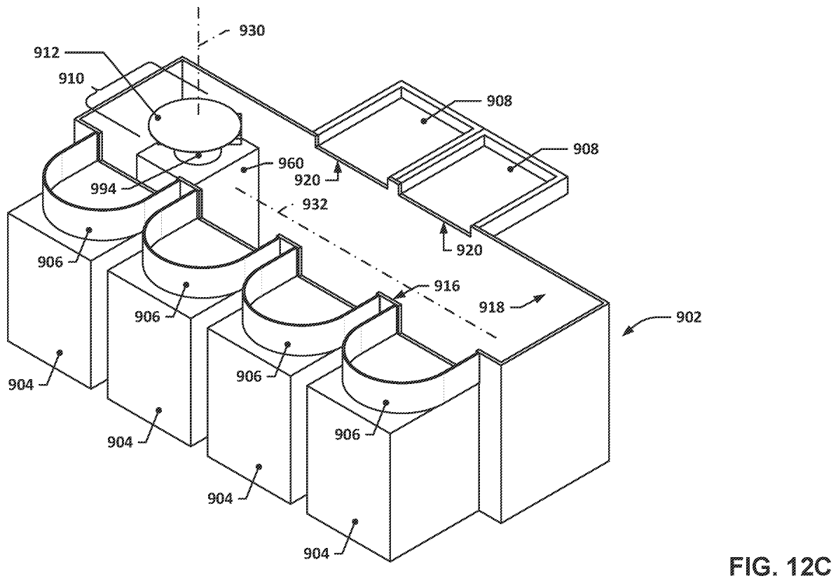

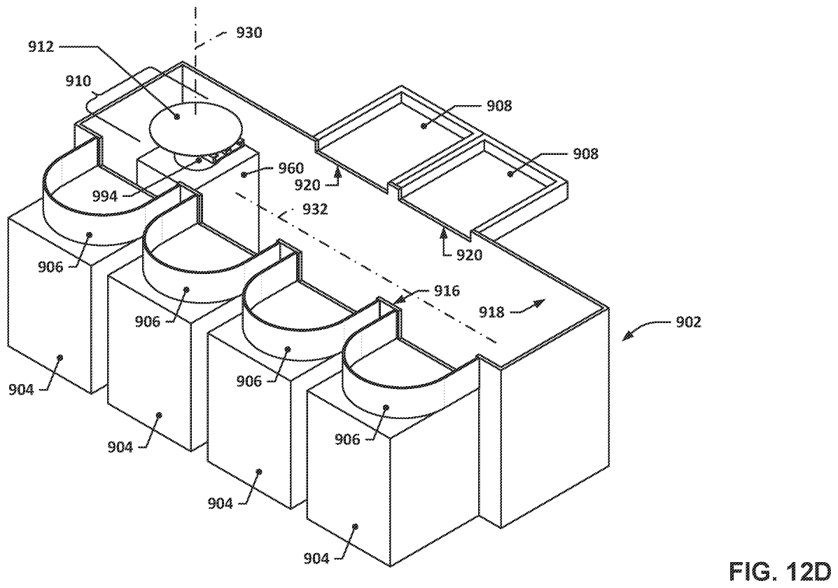

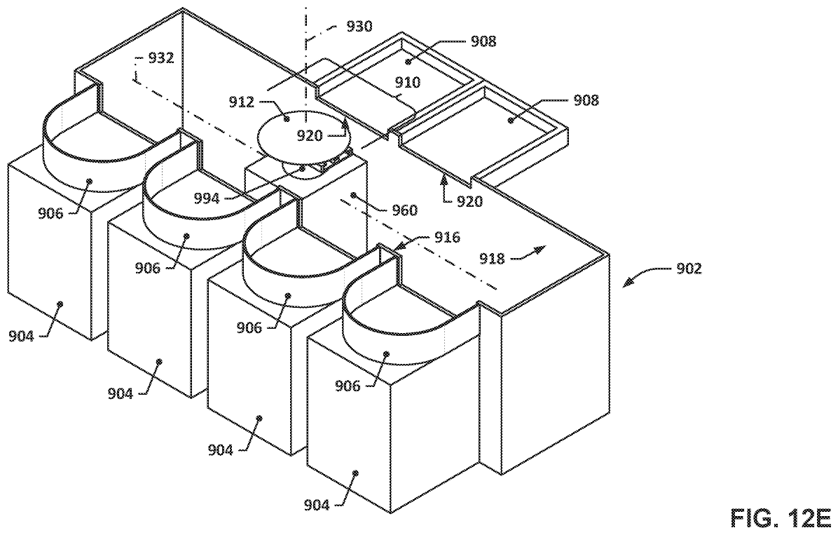

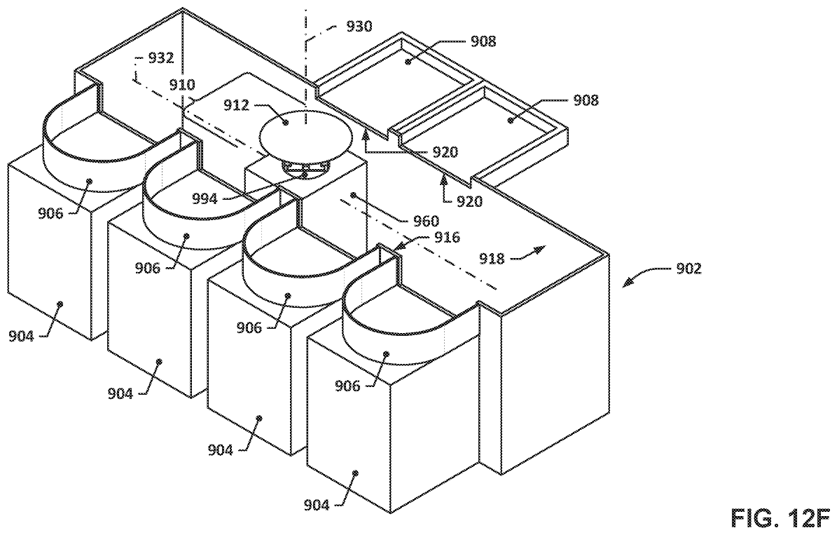

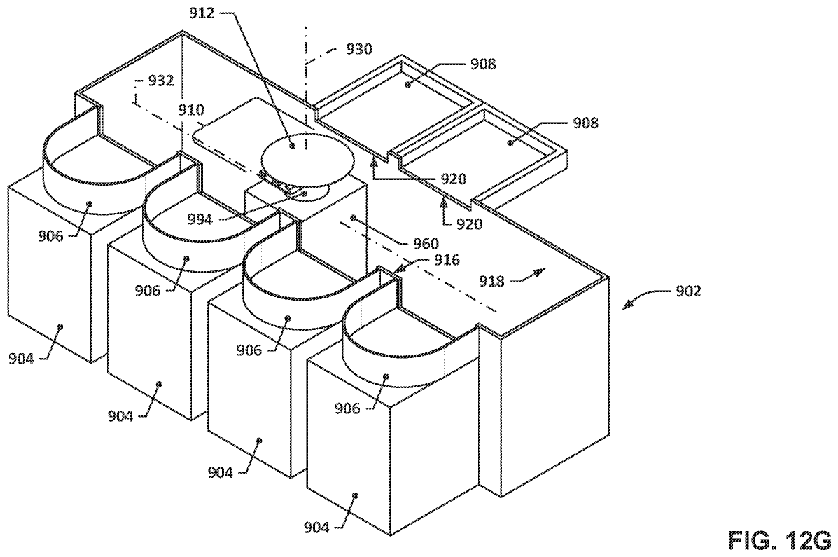

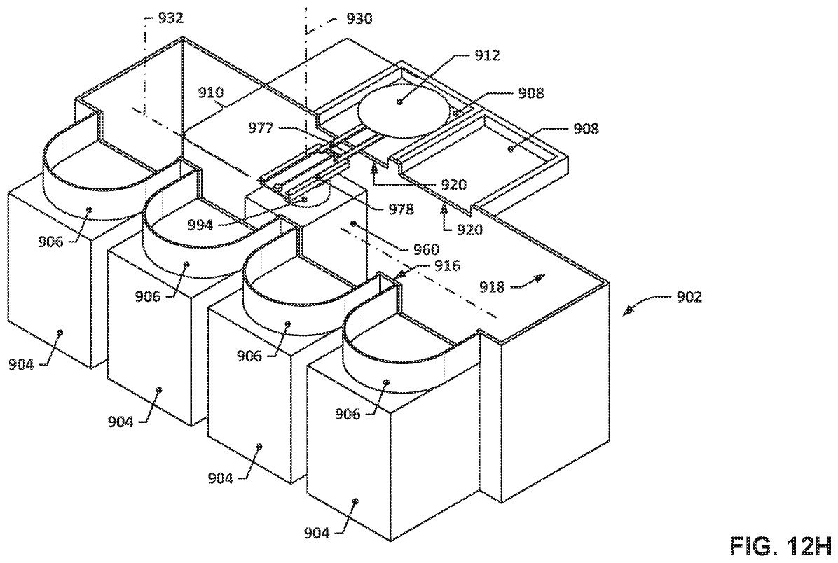

FIGS. 12A through 12H depict an example EFEM in which the telescoping robot arm 974 is used.

As can be seen, the EFEM includes an EFEM enclosure 902 that has a first wall 916 and a second wall 918. The first wall 916 may have a plurality of load ports 904 interfaced therewith, e.g., mounted to a bolt plane (not shown) defined by the first wall 916. Each load port 904 may be configured to receive and locate a FOUP 906. The second wall 918 may have one or more load locks 908 interfaced therewith; the load locks 908 may be accessible via load lock openings 920.

The EFEM enclosure 902 may further include a first robot arm base 960 that rotatably supports a first robot arm 910, which, in this example, is the telescoping robot arm 974. The first robot arm base 960 may, for example, include a turret 994 that may house a rotational drive that may be controlled to cause the first robot arm 910 to rotate relative to the first robot arm base 960 and about a first axis 930. The first robot arm base 960 may be supported by a first linear translation system (not shown but see earlier examples herein) that is configured to controllably move the first robot arm base 960 along a second axis 932. Thus far, the system illustrated in FIGS. 12A through 12H is generally similar to, for example, the implementation of FIGS. 1A through 1K.

As noted earlier, the telescoping robot arm 974 that is used as the first robot arm 910 is able to transition between an extended state and a retracted state. In the extended state, the first portion 976 is able to reach into one of the FOUPs 906 far enough to be able to pick or place the wafer 912 therefrom or therein or reach into one of the load locks 908 far enough to be able to pick or place the wafer 912 therefrom or therein. In the retracted state, the first robot arm 910, at least when positioned directly in front of one of the FOUPs 906 or the load locks 908, can be rotated through at least 90 degrees so as to align the extension axis with the second axis 932 without the first robot arm 910 or a wafer 912 supported thereby colliding with any components or structures within the EFEM enclosure 902.

For example, as can be seen in FIG. 12A, the first robot arm 910 is in the extended state, and the wafer 912 is positioned within the left-most FOUP 906. In FIG. 12B, the first portion 976 and the second portion 977 of the first robot arm 910 have been caused to be transitioned to the retracted state, and in FIGS. 12C through 12D, the first robot arm 910 has been caused to rotate by 90°. In FIG. 12E, the first robot arm base 960 has been caused to translate to the right along the second axis 932 so as to be positioned in front of the left-hand load lock 908. In FIGS. 12F and 12G, the first robot arm 910 has been caused to rotate another 90° so as to align the extension axis so as to be perpendicular to the second axis 932. In FIG. 12H, the first robot arm 910 has been caused to be transitioned to the extended state, thereby introducing the wafer 912 into the left-hand load lock 908. It will be apparent that similar movements may be used to access wafers 912 located in, or deliver wafers 912 to, any of the load locks 908 or FOUPs 906 that are depicted in FIGS. 12A through 12H.

It will be understood that the location of the first axis in the implementation of FIGS. 12A through 12H may be located in a similar manner to where the first axis is located in the other implementations discussed above. Moreover, the first robot arm base 960 may also be equipped with a vertical lift mechanism that allows the turret 994 to be raised and lowered, as needed, so that the first robot arm 910 may be moved between different elevations, e.g., so as to be able to pick wafers from different levels within the FOUPs 906.

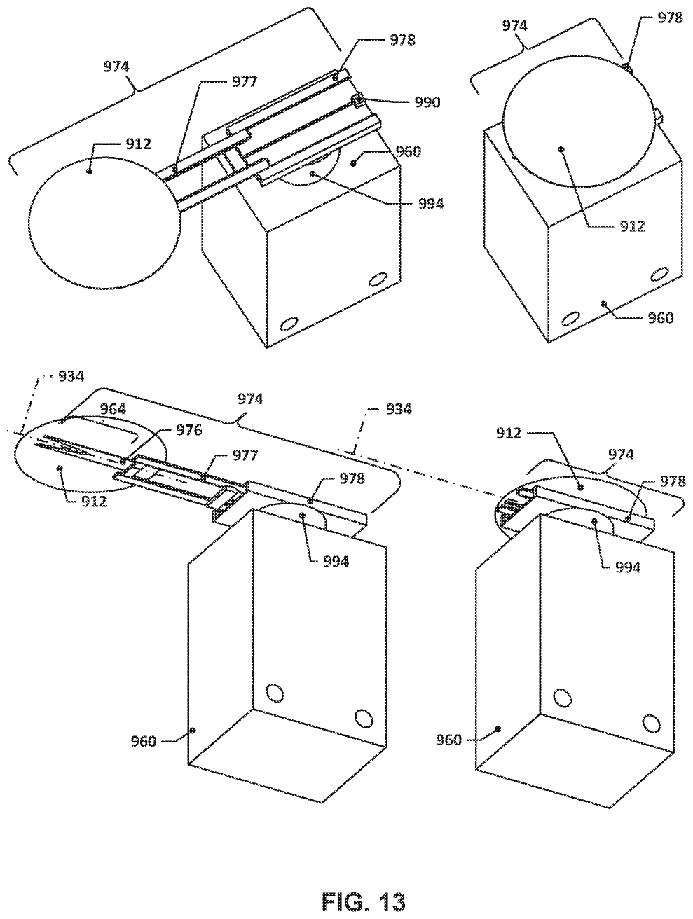

FIG. 13 depicts various views of the telescoping robot arm of FIGS. 12A through 12H. Visible in FIG. 13 is the first robot arm base 960 that has the turret 994 protruding therefrom. The turret 994 support the telescoping robot arm 974 that includes the first portion 976, the second portion 977, and the third portion 978. The third portion 978 is mounted to the turret 994 so that when the turret 994 is caused to rotate, extend, or retract relative to the first robot arm base 960, the third portion 978, the second portion 977, and the first portion 976 rotate, extend, or retract with it.

The first portion 976 includes an end effector 964 that is configured to support a wafer 912. As discussed earlier, the telescoping robot arm 974 may be configured to extend or retract along an extension axis 934, which may also be referred to herein as a third axis.

It will be appreciated that the telescoping arm depicted in FIG. 13 is simply one example of such a mechanism; other implementations may use other types of telescoping arm mechanisms, which are also considered to be within the scope of this disclosure.

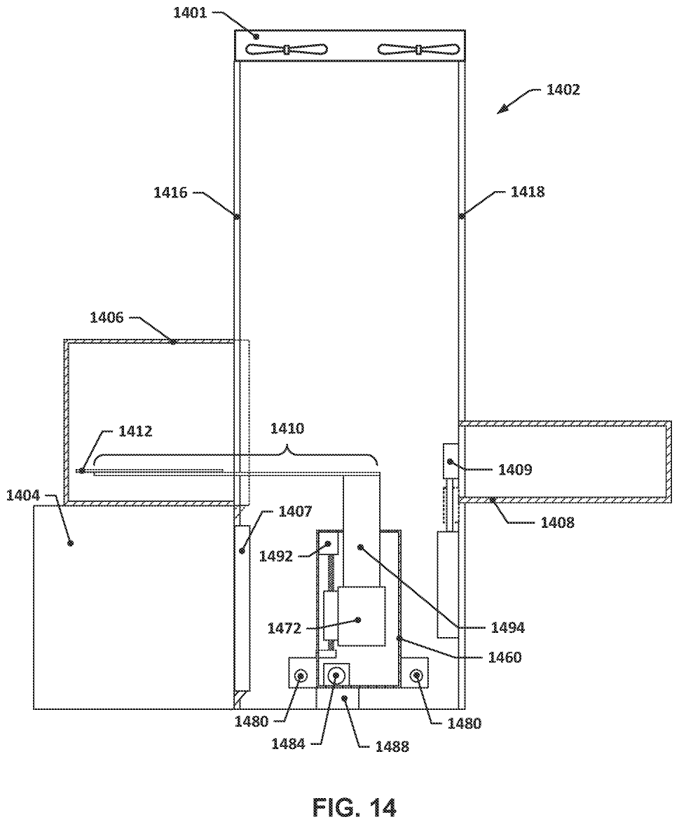

FIG. 14 depicts a side view of an example EFEM enclosure according to the present disclosure; while the depicted implementation features a non-telescoping first robot arm, it will be understood that the same configuration may be used with a telescoping first robot arm. It will also be understood that the example implementations discussed above may also feature similar such systems.

In FIG. 14, an EFEM enclosure 1402 is shown that has a first wall 1416 and an opposing second wall 1418. The first wall 1416 has butted up against it a plurality of load ports 1404 (although only one is visible). Each load port may support a FOUP 1406 and may have a mechanism that is configured to allow a FOUP door 1407 to be removed from the FOUP 1406 that is supported thereby and moved downward so as to no longer block access to the interior of the FOUP 1406 by a first robot arm 1410 that is located inside the EFEM enclosure 1402.

The second wall 1418 may be interfaced with one or more load locks 1408. Each load lock 1408 may have a corresponding load lock door 1409 that may be moved, in a manner similar to the FOUP doors 1407, between an open and a closed position so as to seal the load lock 1408 off from the EFEM enclosure 1402 or to allow access to the interior of the load lock 1408 by the first robot arm 1410.

The EFEM enclosure 1402 may also include a fan filter unit 1401 that may be located at the top of the EFEM enclosure 1402. The fan filter unit 1401 may be equipped with blower fans that may be controlled so as to direct a flow of forced air down through the EFEM enclosure 1402. The fan filter unit 1401 may also include one or more filters that may filter the air that is forced through the EFEM enclosure 1402 so as to reduce or prevent particulate contamination.

As can be seen, the first robot arm 1410 may be connected with a turret 1494 that protrudes from a first robot arm base 1460. The first robot arm base 1460 may have within it a vertical lift mechanism 1492, e.g., a motor that causes a linear screw drive to turn and drive the turret 1494 up or down relative to the first robot arm base 1460. The vertical lift mechanism 1492 may be connected with an arm rotation motor 1472; the arm rotation motor 1472 may, in turn, have a rotational output which may be connected with the turret 1494 such that when the rotational output of the arm rotation motor 1472 is caused to rotate, the turret 1494 (and the first robot arm connected therewith) is also caused to rotate.

The first robot arm base 1460 may be supported within the EFEM enclosure 1402 by way of first linear guides 1480. A first drive screw 1484 may pass through a nut that is fixedly mounted with respect to the first robot arm base 1460 so that when the first drive screw 1484 is caused to rotate, e.g., through rotational input delivered by a first drive motor 1488, the first robot arm base 1460 is caused to traverse along the first linear guides 1480.

This general structure, or other structures that may provide similar functionality, may be used in any of the implementations discussed above to allow a wafer 1412 to be moved between the FOUPs 1406 and the load locks 1408.

The control of a shallow-depth EFEM, e.g., the operation of the robot arm(s) that may be located inside, the various door opening mechanisms thereof, etc., may be facilitated through the use of a controller that may be included as part of a semiconductor processing tool having the shallow-depth EFEM or which may be part of the shallow-depth EFEM itself. The systems discussed above may be integrated with electronics for controlling their operation before and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including valve or door operation, wafer retrieval from or placement into a FOUP, wafer retrieval from or placement into a load lock, the rotation of a robot arm relative to the base that supports it, the translation of a robot arm base, the vertical movement of a robot arm, etc.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular wafer transfer operation within a shallow-depth EFEM. The operational parameters may, in some embodiments, define movement paths that are designed to convey a wafer between two locations serviced by the shallow-depth EFEM.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a wafer transfer operation in the shallow-depth EFEM.

Without limitation, example systems that the load lock(s) of a shallow-depth EFEM may be connected with, either directly or via an intervening vacuum transfer module, include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers, e.g., FOUPs, to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
an equipment front-end module (EFEM) enclosure for handling semiconductor wafers having a nominal diameter of D, the EFEM enclosure having a first wall defining a bolt plane for load ports and a second wall opposite the first wall and defining a load lock plane, wherein the bolt plane and the load lock plane are spaced apart from one another by a first distance greater than D and less than 1.75 D;
a first robot arm base located within the EFEM enclosure;
a first robot arm supported by, and coupled with, the first robot arm base such that the first robot arm is rotatable relative to the first robot arm base about a first axis, wherein the first axis is located within 40% to 60% of the first distance from the bolt plane and within 40% to 60% of the first distance from the load lock plane; and
a first linear translation system configured to move the first robot arm base along a second axis parallel to the bolt plane.

2. The apparatus of claim 1, wherein the first distance is greater than D and less than 1.65 D.

3. The apparatus of claim 2, wherein the first distance is greater than D and less than 1.6 D.

4. The apparatus of claim 1, further comprising a plurality of load ports arranged in a linear array along an exterior of the first wall, each load port having a corresponding interface configured to receive and locate a corresponding FOUP on that load port such that wafers in that FOUP are nominally centered above a corresponding target location on that load port, wherein:
the two load ports of the plurality of load ports that are furthest from each other have corresponding target locations that are spaced apart from one another by a distance X, and
the first linear translation system is configured to translate the first robot arm base along the second axis by a second distance of at least X.

5. The apparatus of claim 4, wherein:
the first robot arm includes a first robot arm link that ends in a first end effector configured to support a wafer, and
the first robot arm link and the first end effector are rotationally fixed relative to each other and rotate as a single structure when the first robot arm link is caused to rotate relative to the first robot arm base.

6. The apparatus of claim 5, wherein a tip of the first end effector furthest from the first axis is a third distance from the first axis and the third distance is greater than 1.3 D.

7. The apparatus of claim 6, wherein the third distance is greater than 1.4 D.

8. The apparatus of claim 7, wherein the third distance is greater than 1.6 D.

9. The apparatus of claim 5, wherein the first robot arm link and the first end effector are fixed, both rotationally and translationally, relative to each other.

10. The apparatus of claim 5, wherein the first linear translation system is configured to translate the first robot arm base along the second axis by a distance of at least X+D.

11. The apparatus of claim 10, wherein the EFEM enclosure:
has opposing end walls spanning between the first wall and the second wall,
a first extension region of the EFEM enclosure is bracketed between one of the end walls and the load port closest thereto, and
the first extension region has a length along the second axis of at least D.

12. The apparatus of claim 10, further comprising:
a second robot arm base located within the EFEM enclosure; and
a second robot arm supported by, and coupled with, the second robot arm base such that the second robot arm is rotatable relative to the first second robot arm base about a rotational axis, wherein the rotational axis is located within 40% to 60% of the first distance from the bolt plane and within 40% to 60% of the first distance from the load lock plane, wherein:
the first linear translation system is further configured to move the second robot arm base along the second axis.

13. The apparatus of claim 12, wherein the EFEM enclosure:
has opposing end walls spanning between the first wall and the second wall,
a first extension region of the EFEM enclosure is bracketed between one of the end walls and the load port closest thereto,
a second extension region of the EFEM enclosure is bracketed between the other of the end walls and the load port closest thereto, and
the first extension region and the second extension region each have a length along the second axis of at least D.

14. The apparatus of claim 4, further comprising one or more alcoves located in the first wall or the second wall, wherein:
each alcove has an interior surface facing towards an interior of the EFEM enclosure that is at least as far from a reference plane coincident with the first axis and parallel to the load lock plane as an end of the first robot arm furthest from the first axis is from the first axis, and
each alcove is sized large enough that the end of the first robot arm furthest from the first axis is insertable into that alcove without coming into contact with walls defining that alcove when the first robot arm is extended such that the end of the first robot arm furthest from the first axis is also furthest from the first wall.

15. The apparatus of claim 14, wherein:
the second wall includes one or more load lock openings,
at least one of the one or more alcoves is located in the second wall and is positioned above or below the load lock openings,
the first robot arm base includes a vertical lift mechanism that is configured to translate the first robot arm between at least a first vertical position and a second vertical position along a vertical axis,
the first robot arm, in the first vertical position, is positioned such that the end of the first robot arm furthest from the first axis is at an elevation that is within a first elevation range spanned by at least one of the one or more load lock openings, and
the first robot arm, in the second vertical position, is positioned such that the end of the first robot arm furthest from the first axis is at an elevation that is within a second elevation range occupied by at least one of the one or more alcoves.

16. The apparatus of claim 14, wherein:
the second wall includes one or more load lock openings, and
at least one of the one or more alcoves is located in the second wall and is positioned to the side of at least one of the load lock openings.

17. The apparatus of claim 1, further comprising a controller having one or more processors and one or more memory devices, the one or more memory devices storing computer-executable instructions for causing the one or more processors to:
a) cause the first linear translation system to move the first robot arm base along the second axis during a first time interval and by a first amount while the first robot arm is in a first rotational position relative to the first robot arm base, and
b) cause the first linear translation system to move the first robot arm base along the second axis during a second time interval and by a second amount while simultaneously causing the first robot arm to rotate relative from the first rotational position relative to the first robot arm base to a second rotational position relative to the first robot arm base, wherein:
the first robot arm, in the first rotational position relative to the first robot arm base, is entirely between the load lock plane and the bolt plane, and
the first robot arm, in the second rotational position relative to the first robot arm base, extends through the bolt plane.

18. The apparatus of claim 17, wherein:
the first robot arm is configured to support a wafer during wafer transfer operations within the EFEM enclosure such that a center point of the wafer is positioned above and centered over a wafer target location defined for the first robot arm, and
the one or more memory devices store further computer-executable instructions for causing the one or more processors to:
cause the first robot arm base to be in a first horizontal position at the start of the second time interval, and
cause, during most or all of the second time interval, the first robot arm to rotate to angular displacements from the first rotational position relative to the first robot arm base determined according to the function
$$a cos ( \frac{\partial }{\text{?}} ) \cdot \frac{18 \text{?}}{\text{?}} ,$$
$$\text{?} \text{indicates text missing or illegible when filed}$$
where δ=a distance from the first axis to the wafer target location, α=the displacement of the first robot arm base from the first horizontal position, and π=the numeric constant pi.

19. The apparatus of claim 5, wherein:
the first robot arm includes a first portion, a second portion, and a third portion;
the third portion is rotatably connected with the first robot arm base;
the first portion includes an end effector; and
the first portion is configured to translate relative to the second portion, and the second portion relative to the third portion, such that the first robot arm is able to be transitioned between an extended state and a retracted state responsive to receipt of one or more control signals.

20. The apparatus of claim 19, wherein the first portion, the second portion, and the third portion each have a length that is equal to or less than D.

21. The apparatus of claim 19, wherein the first robot arm is configured such that the first portion moves relative to the second portion simultaneously with movement of the second portion relative to the third portion.

22. The apparatus of claim 21, wherein:
the first portion is connected with the third portion by one or more pairs of belt portions, and
each belt portion passes over a corresponding pulley that is rotatably mounted to the second portion.

23. The apparatus of claim 19, further comprising a second linear translation system configured to cause the second portion to translate relative to the first portion.

24. The apparatus of claim 4, wherein:
the first robot arm includes a first robot arm link that is configured to be rotatable relative to the first robot arm base about the first axis,
the first robot arm further includes a second robot arm link that is rotatably connected with the first robot arm link so as to be rotatable relative to the first robot arm link, and
the first robot arm is configured such that the second robot arm link is configured to be rotatable relative first robot arm link independent of rotation of the first robot arm link relative to the first robot arm base.

25. The apparatus of claim 24, wherein:
the second robot arm link is configured to rotate about an elbow axis relative to the first robot arm link,
the second robot arm link includes a first end effector configured to support a wafer such that the wafer is centered on a target location that is fixed with respect to the first end effector, and
a first distance between the target location and the elbow axis is greater than a second distance between the elbow axis and the first axis.

26. The apparatus of claim 25, wherein the second distance is less than D.

27. The apparatus of claim 25, wherein a distance between the first axis and the portion or portions of the first robot arm link that are furthest from the first axis is less than or equal to D.
